(19) United States
(12) Patent Application Publication
(10) Pub. No.: US 2026/0198120 A1
(43) Pub. Date: Jul. 9, 2026

(54) IMAGE SENSOR

(71) Applicant: Samsung Electronics Co., Ltd., Suwon-si (KR)

(72) Inventors: Jihyun Kwak, Suwon-si (KR); Jinyoung Kim, Suwon-si (KR); Jonghyun Go, Suwon-si (KR); Haneul Kim, Suwon-si (KR); Changkyu Lee, Suwon-si (KR); Haejung Lee, Suwon-si (KR)

(21) Appl. No.: 19/332,642

(22) Filed: Sep. 18, 2025

(30) Foreign Application Priority Data
Jan. 7, 2025 (KR) 10-2025-0002399

(51) Int. Cl. H10F 39/00

(52) U.S. Cl. CPC H10F 39/8063; H10F 39/8053; H10F 39/8057

(57) ABSTRACT

An image sensor includes a substrate including a pixel region and a peripheral region surrounding the pixel region, in which a plurality of pixels are arranged in the pixel region, a plurality of color filters disposed above the substrate, at least one meta-microlens array disposed above the plurality of color filters and including a plurality of nanoposts and a dielectric layer between the plurality of nanoposts, and a planarization layer located between the plurality of color filters and the at least one meta-microlens array, in which the planarization layer is in contact with the plurality of color filters and includes an inorganic material.

### CROSS-REFERENCE TO RELATED APPLICATION

This application is based on and claims priority under 35 U.S.C. § 119 to Korean Patent Application No. 10-2025-0002399, filed on Jan. 7, 2025, in the Korean Intellectual Property Office, the disclosure of which is incorporated by reference herein in its entirety.

### BACKGROUND

Image sensors typically sense color of incident light by using a color filter. However, the color filter absorbs light of colors other than light of the corresponding color, and thus, efficiency of light utilization may deteriorate. For example, when an RGB color filter is used, only one-third of incident light is transmitted, and the remaining two-thirds of the incident light is absorbed and discarded. Accordingly, the efficiency of light utilization is only about 33%. Therefore, when using color display devices or color image sensors, most optical loss occurs in the color filter.

### SUMMARY

In general, the present disclosure is directed toward an image sensor that may be easily manufactured.

According to some implementations, the present disclosure is directed to an image sensor that includes a substrate including a pixel region and a peripheral region surrounding the pixel region, wherein a plurality of pixels are arranged in the pixel region, a plurality of color filters disposed above the substrate, at least one meta-microlens array disposed above the plurality of color filters and including a plurality of nanoposts and a dielectric layer between the plurality of nanoposts, and a planarization layer located between the plurality of color filters and the at least one meta-microlens array, wherein the planarization layer is in contact with the plurality of color filters and includes an inorganic material.

According to some implementations, the present disclosure is directed to an image sensor that includes a substrate including a pixel region and a peripheral region surrounding the pixel region, wherein a plurality of pixels are arranged in the pixel region, an anti-reflection structure disposed on the substrate, a plurality of color filters disposed above the anti-reflection structure, in the pixel region, at least one meta-microlens array disposed above the plurality of color filters and including a plurality of nanoposts and a dielectric layer between the plurality of nanoposts, and a planarization layer located between the plurality of color filters and the at least one meta-microlens array, wherein the pixel region includes a pixel array region, in which the plurality of pixels are arranged, and a light-blocking region in which a light-blocking layer is located, and the planarization layer is in contact with the plurality of color filters and the light-blocking layer and includes an inorganic material.

According to some implementations, the present disclosure is directed to an image sensor that includes a first substrate including a pixel region and a peripheral region surrounding the pixel region, wherein a plurality of pixels are arranged in the pixel region, and the first substrate has a front side and a back side opposite to the front side, a first wire layer on the back side of the first substrate, an anti-reflection structure on the front side of the first substrate, a second substrate below a lower surface of the first wire layer, a second wire layer located between the second substrate and the first wire layer, a plurality of color filters disposed above the anti-reflection structure, in the pixel region, at least one meta-microlens array disposed above the plurality of color filters and including a plurality of nanoposts and a dielectric layer between the plurality of nanoposts, and a planarization layer located between the plurality of color filters and the at least one meta-microlens array, wherein the pixel region includes a pixel array region, in which the plurality of pixels are arranged, and a light-blocking region in which a light-blocking layer is located, the peripheral region includes a contact region in which a back-side contact is located, a back-side via region in which a back-side via is located, and a pad region in which a pad is located, the back-side contact extends through the anti-reflection structure from above the anti-reflection structure to a deep trench isolation, wherein the deep trench isolation separates the plurality of pixels from each other, and the planarization layer is in contact with the plurality of color filters and the light-blocking layer and includes an inorganic material.

### BRIEF DESCRIPTION OF THE DRAWINGS

Example implementations will be more clearly understood from the following detailed explanations, taken in conjunction with the accompanying drawings.

FIG. 1 is a block diagram of an example of an image sensor according to some implementations.

FIG. 2 is a perspective view of the image sensor of FIG. 1 according to some implementations.

FIG. 3 is an equivalent circuit diagram of examples of unit pixels in a pixel region of the image sensor of FIG. 1 according to some implementations.

FIG. 4 is a plan view of the image sensor of FIG. 1 according to some implementations.

FIG. 5 is a cross-sectional view of an example of an image sensor taken along line A-A′ of FIG. 4 according to some implementations.

FIG. 6 is a cross-sectional view of an example of an image sensor in an area corresponding to a cross-section taken along line A-A′ of FIG. 4 according to some implementations.

FIG. 7 is a cross-sectional view of an example of an image sensor in an area corresponding to a cross-section taken along line A-A′ of FIG. 4 according to some implementations.

FIG. 8 is a cross-sectional view of an example of an image sensor in an area corresponding to a cross-section taken along line A-A′ of FIG. 4 according to some implementations.

FIG. 9 is a cross-sectional view of an example of an image sensor in an area corresponding to a cross-section taken along line A-A′ of FIG. 4 according to some implementations.

FIG. 10 is a plan view of an example of an image sensor corresponding to the image sensor of FIG. 1 according to some implementations.

FIG. 11 is a cross-sectional view of the image sensor taken along line B-B′ of FIG. 10 according to some implementations.

FIG. 12 is a block diagram of an example of an electronic device including a multi-camera module according to some implementations.

FIG. 13 is a detailed block diagram of the camera module of FIG. 12 according to some implementations.

FIG. 14 is a block diagram showing an example of a configuration of an image sensor according to some implementations.

FIG. 15 is a block diagram schematically showing an example of an electronic device including an image sensor according to some implementations.

FIG. 16 is a block diagram schematically showing an example of a camera module of FIG. 15 according to some implementations.

### DETAILED DESCRIPTION

Hereinafter, example implementations will be described in detail with reference to the accompanying drawings. The same reference numerals are given to the same elements in the drawings, and repeated descriptions thereof are omitted. In the following drawings, the thickness and size of each layer are exaggerated for convenience and clarity of description, and may be slightly different from the actual shape and proportions thereof.

As used herein, terms representing spatial relationships, such as “bottom,” “below,” “lower,” “top,” and “upper,” are intended only to describe relative positional relationships between elements or patterns shown in the drawings, and are used for ease of understanding only and do not limit the inventive concept at all. The terms for the relative positions in space are intended to encompass changes due to the orientation of a semiconductor device in addition to the directions shown in the drawings. That is, the semiconductor device may be oriented in various directions when used (or manufactured), and the terms for the positions used herein are easily understood by a person skilled in the art.

As used herein, the term “about” in reference to a numerical value or range is intended to account for variations that may arise due to limitations in measurement precision and variability in fabrication or experimental techniques that would be recognized by one of ordinary skill in the art. The degree of permissible variation will depend on the specific context, including the sensitivity of the value to the operation or effect described. In general, “about” is intended to encompass values that are close enough to achieve substantially the same technical result or function as the stated value or range.

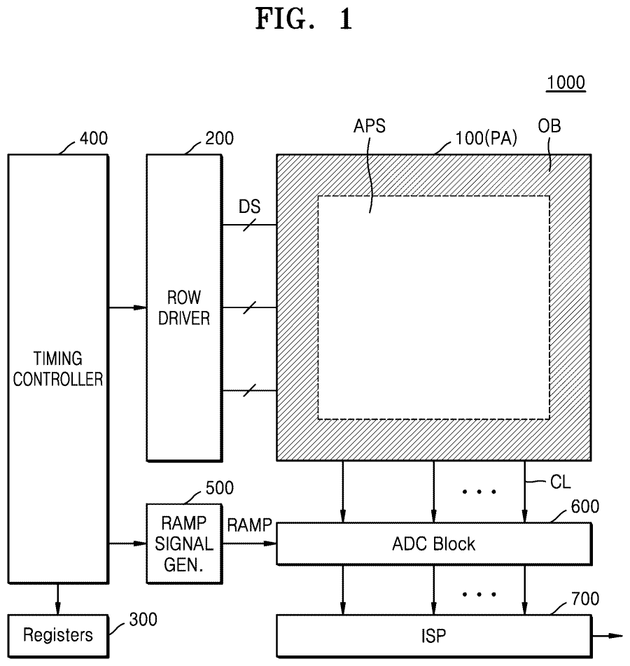

FIG. 1 is a block diagram of an example of an image sensor 1000 according to some implementations. In FIG. 1, the image sensor 1000 may include a pixel region 100, a row driver 200, a mode setting register 300, a timing controller 400, a ramp signal generator 500, an analog-to-digital converter (ADC) block 600, and a signal processing unit 700.

The pixel region 100 may include a pixel array region APS and a light-blocking region OB. As shown in FIG. 1, the pixel array region APS may be located in a central region of the pixel region 100, and the light-blocking region OB may be located in an outer peripheral region of the pixel region 100 while surrounding the pixel array region APS. For reference, according to some implementations, the pixel array region APS may be referred to as an active pixel sensor region, and the light-blocking region OB may be referred to as an optical black pixel region. The pixel array region APS and the light-blocking region OB may each include a plurality of unit pixels arranged in two dimensions. The plurality of unit pixels may each convert an optical signal into an electrical signal. The unit pixels in the pixel region 100 may output the electrical signal through a corresponding column line CL in response to a plurality of driving signals DS, such as a pixel selection signal, a reset signal, and a charge transfer signal, from the row driver 200 in units of rows.

The row driver 200 may select and drive the unit pixels of the pixel region 100 in units of rows. The row driver 200 may decode a row control signal (e.g., an address signal) received from the timing controller 400, generate the plurality of driving signals DS corresponding to the decoded row line, and transmit these generated signals to the pixel region 100.

The mode setting register 300 may include a register configured such that an application processor (AP) connected to the image sensor 1000 sets an operating mode of the image sensor 1000 through an interface. The AP may change an operating condition of the image sensor 1000 in units of frames through the mode setting register 300.

The timing controller 400 may collectively control operations of circuit blocks (e.g., 200, 400, and 500) of the image sensor 1000 according to mode setting information that is set in the mode setting register 300.

The ramp signal generator 500 may generate a ramp signal RAMP that increases or decreases at a certain rate and may then provide the ramp signal RAMP to the ADC block 600.

The ADC block 600 may convert an analog electric signal output from column lines CL of the pixel region 100 into a digital image signal by a correlated double sampling (CDS) method. In the CDS method, a noise level and a signal level of a unit pixel transmitted via a column line are sampled in a dual manner, and a difference level corresponding to the difference between the noise level and the signal level may be converted into and generated as a digital image signal.

The signal processing unit 700 may process the received image signal and output a final image signal. The signal processing performed by the signal processing unit 700 may include noise reduction processing, gain adjustment, waveform shaping processing, interpolation processing, white balance processing, gamma processing, edge enhancement processing, binning, etc.

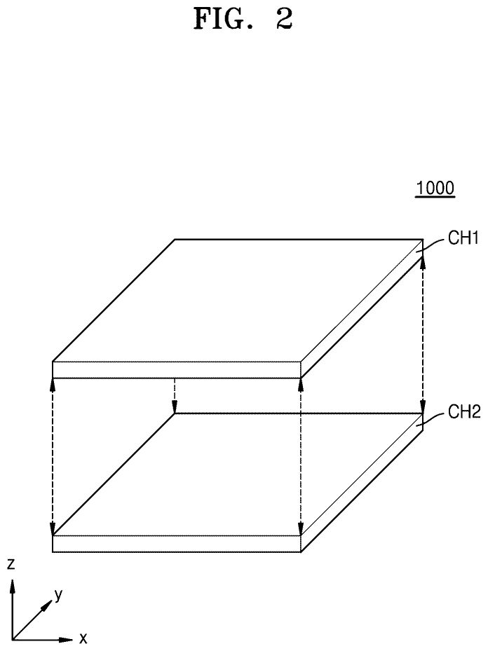

FIG. 2 is a perspective view of the image sensor 1000 of FIG. 1 according to some implementations that individually shows a first semiconductor chip CH1 and a second semiconductor chip CH2. A description is given below with reference to FIG. 1 together, and descriptions already given with reference to FIG. 1 are simplified or omitted.

In FIG. 2, the image sensor 1000 may include two semiconductor chips, such as the first and second semiconductor chips CH1 and CH2. The pixel region 100 of the image sensor 1000 of FIG. 1 may be located in the first semiconductor chip CH1. All circuit blocks (e.g., 200 to 700) other than the pixel region 100 of the image sensor 1000 of FIG. 1 may be arranged in the second semiconductor chip CH2. The first semiconductor chip CH1 and the second semiconductor chip CH2 may be vertically stacked on each other. The first semiconductor chip CH1 and the second semiconductor chip CH2 may transmit signals to each other via respective wire layers, and a through silicon via (TSV) passing through the first semiconductor chip CH1 or an inter-chip connection terminal.

In FIGS. 2 to 11, a direction parallel to a main surface of the first semiconductor chip CH1 is defined as a horizontal direction (an x direction and/or a y direction), and a direction perpendicular to the horizontal direction (the x direction and/or the y direction) is defined as a vertical direction (a z direction).

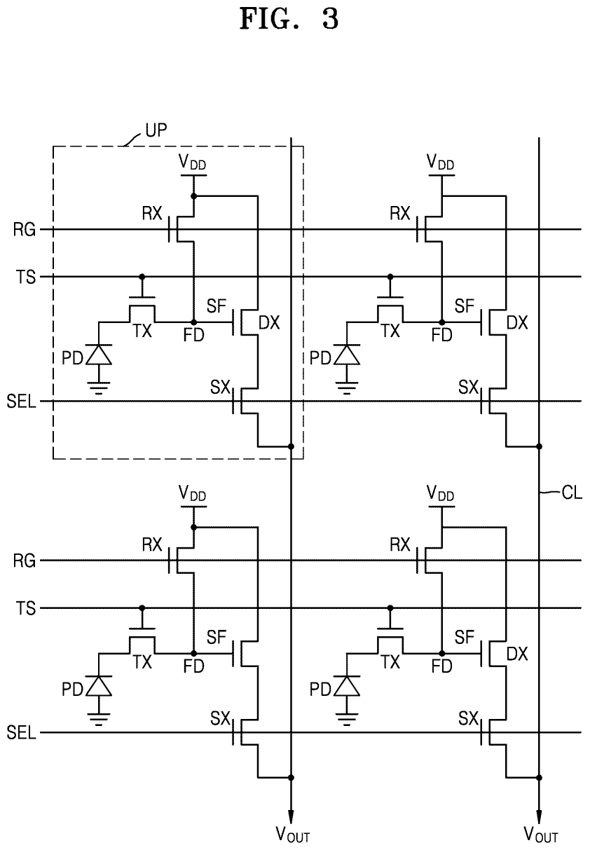

In some implementations, the image sensor 1000 may include three semiconductor chips stacked on one another. In the three stacked semiconductor chips, a first semiconductor chip located uppermost has the pixel region 100 and some of components constituting a unit pixel. For example, the first semiconductor chip may have a photodiode PD (see FIG. 3) constituting the unit pixel, a transfer transistor TX (see FIG. 3), and a floating diffusion region FD (see FIG. 3). A second semiconductor chip located below the first semiconductor chip may also have the pixel region 100, and pixel transistors other than the transfer transistor TX, such as a reset transistor RX (see FIG. 3), a source follower transistor DX (see FIG. 3), and a selection transistor SX (see FIG. 3). The transfer transistor TX and the floating diffusion region FD of the first semiconductor chip may be connected to the corresponding pixel transistors (e.g., RX, DX, and SX) of the second semiconductor chip via a TSV or an inter-chip connection terminal. A third semiconductor chip located below the second semiconductor chip may have circuit blocks (e.g., 200 to 700) other than the pixel region 100. The third semiconductor chip may be connected to the second semiconductor chip via a TSV or an inter-chip connection terminal.

FIG. 3 is an equivalent circuit diagram of examples of unit pixels in the pixel region of the image sensor of FIG. 1 according to some implementations. A description is given below with reference to FIG. 1 together, and descriptions already given with reference to FIGS. 1 and 2 are simplified or omitted.

In FIG. 3, the pixel region 100 may include a plurality of unit pixels UP, and the unit pixels UP may be arranged in a two-dimensional array structure. A unit pixel UP may include the photodiode PD and pixel transistors. The pixel transistors may include the transfer transistor TX, the reset transistor RX, the source follower transistor DX, and the selection transistor SX. Also, the unit pixel UP may include the floating diffusion region FD which is connected to source/drain of the transfer transistor TX and the reset transistor RX and to a gate of the source follower transistor DX.

The photodiode PD may generate and accumulate electric charges in proportion to an amount of light incident from the outside during an exposure time. In the image sensor 1000 according to the inventive concept, a phototransistor, a photogate, a pinned photodiode, or the like may be arranged instead of the photodiode PD. Elements that convert light into electric charges are referred to as photoelectric conversion elements.

The transfer transistor TX may transmit the electric charges, which have been accumulated in the photodiode PD during the exposure time, to the floating diffusion region FD in response to a transfer control signal TS. The floating diffusion region FD may store the electric charges that are transferred from the photodiode PD via the transfer transistor TX. The voltage of a gate of the source follower transistor DX may be determined by the amount of electric charges stored in the floating diffusion region FD.

The reset transistor RX may reset the electric charges stored in the floating diffusion region FD. A source of the reset transistor RX may be connected to the floating diffusion region FD and a drain thereof may be connected to a power supply voltage V_{DD}. When the reset transistor RX is turned on by a reset control signal RG, the power supply voltage V_{DD} of the drain of the reset transistor RX may be applied to the floating diffusion region FD to discharge the electric charges. Therefore, when the reset transistor RX is turned on, all electric charges stored in the floating diffusion region FD may be discharged, and the voltage of the floating diffusion region FD may be reset to the power supply voltage V_{DD}.

The source follower transistor DX may include a gate connected to the floating diffusion region FD, a drain connected to the power supply voltage V_{DD}, and a source connected to the selection transistor SX. The source follower transistor DX may act as a source follower buffer amplifier that generates an output voltage at a source in response to voltage at a gate.

The selection transistor SX may transmit the output voltage of the source of the source follower transistor DX to the column line CL in response to a column selection signal SEL. That is, the source follower transistor DX and the selection transistor SX may sense a voltage change in the floating diffusion region FD and output an output voltage V_{OUT} via the column line CL.

In the unit pixel UP of FIG. 3, one floating diffusion region FD and the corresponding pixel transistors (e.g. RX, DX, and SX) may be arranged in one photodiode PD at a ratio of 1:1. However, a unit pixel that constitutes a high-resolution image sensor may have a shared pixel structure in which a plurality of photodiodes PD share one floating diffusion region FD and the corresponding pixel transistors (e.g., RX, DX, and SX).

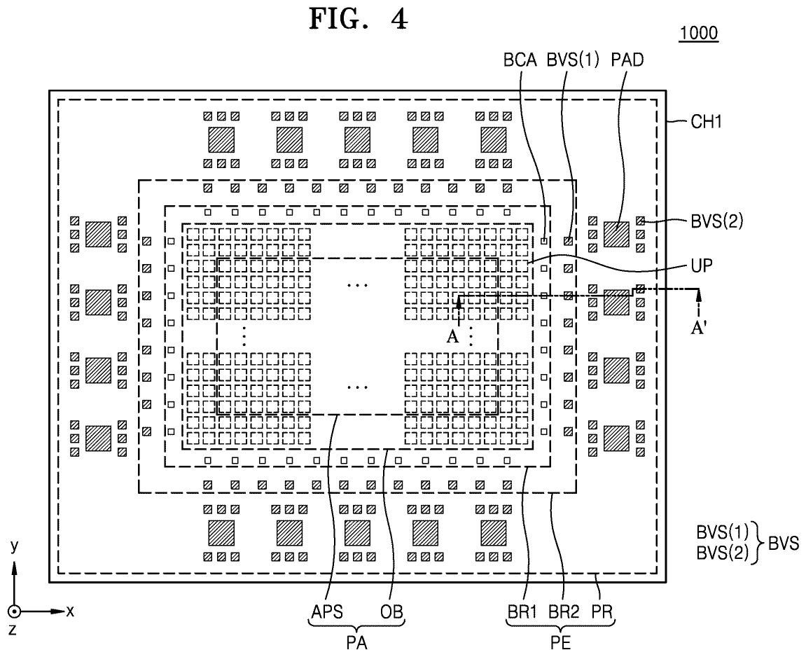

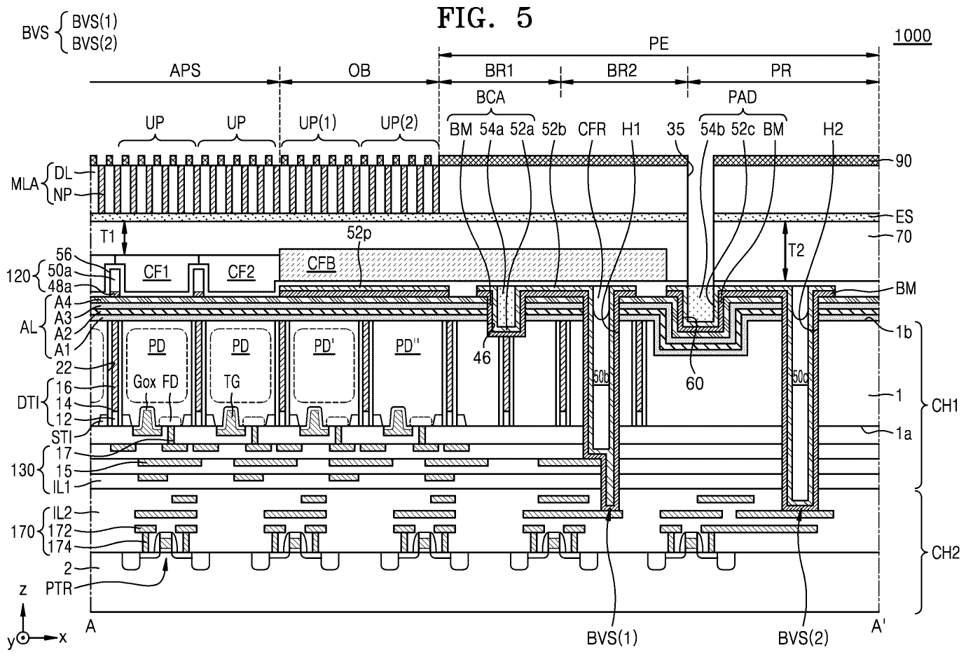

FIG. 4 is a plan view of the image sensor 1000 of FIG. 1 according to some implementations, and FIG. 5 is a cross-sectional view of the image sensor 1000 taken along line A-A′ of FIG. 4 according to some implementations. A description is given below with reference to FIG. 1 together, and descriptions already given with reference to FIGS. 1 to 3 are simplified or omitted.

In FIG. 4 and FIG. 5, the image sensor 1000 may include the first semiconductor chip CH1 and the second semiconductor chip CH2 as described above. The first semiconductor chip CH1 may be stacked on the second semiconductor chip CH2.

The first semiconductor chip CH1 may include a first substrate 1. The first substrate 1 may include silicon (Si). The first substrate 1 may include, for example, a silicon single crystal substrate, a silicon epitaxial layer substrate, or a silicon on insulator (SOI) substrate. However, the material of the first substrate 1 is not limited to Si. For example, the first substrate 1 may include another single-element semiconductor, such as germanium (Ge), or a compound semiconductor, such as silicon carbide (SiC), gallium arsenide (GaAs), indium arsenide (InAs), and indium phosphide (InP). The first substrate 1 may be doped with, for example, first conductivity-type impurities. Here, the first conductivity-type may represent a P type. However, the first conductivity-type is not limited to the P type. The first substrate 1 may include a front side 1a and a back side 1b facing each other. Here, the front side 1a may correspond to an active surface, and the back side 1b may correspond to a non-active surface.

In a plan view of the first semiconductor chip CH1, the image sensor 1000 may include a pixel region PA and a peripheral region PE. The pixel region PA may include the pixel array region APS and the light-blocking region OB, as described in FIG. 1. The plurality of unit pixels UP may be formed inside the first substrate 1 in the pixel array region APS and the light-blocking region OB. As shown in FIG. 4, the light-blocking region OB may surround the pixel array region APS. FIG. 4 illustrates that the pixel array region APS has a small area in a central region, and the light-blocking region OB and the peripheral region PE have relatively large areas, but this is for convenience of illustration. In some implementations, the pixel array region APS may occupy most of the first semiconductor chip CH1, and the light-blocking region OB and the peripheral region PE may be arranged in a small area outside of the pixel array region APS.

The peripheral region PE may surround the pixel region PA, i.e., the light-blocking region OB. The peripheral region PE may include, for example, a contact region BR1, a back-side via region BR2, and a pad region PR. The contact region BR1 may be located adjacent to the light-blocking region OB. In the contact region BR1, back-side contacts BCA may be arranged at certain intervals along a line surrounding the light-blocking region OB.

The back-side via region BR2 may be located between the contact region BR1 and the pad region PR. In the back-side via region BR2, the first back-side vias BVS(1) may be arranged. In FIG. 4, the first back-side vias BVS(1) are arranged in a single row in a form surrounding the contact region BR1. However, the present disclosure is not limited thereto, and the first back-side vias BVS(1) may be arranged in the back-side via region BR2, for example, in a two-dimensional array structure. Also, the first back-side vias BVS(1) are arranged adjacent to all sides of the contact region BR1, but the present disclosure is not limited thereto. The first back-side vias BVS(1) may not be arranged on at least one side of the contact region BR1. In some implementations, a shield region may be defined between the contact region BR1 and the pad region PR, and the back-side via region BR2 may be located in part of the shield region.

The pad region PR may be located outermost in the peripheral region PE. In the pad region PR, second back-side vias BVS(2) and pads PAD may be arranged. FIG. 4 illustrates the pad region PR has a wide width, but this is exaggerated to show arrangement of the pads PAD and the back-side vias BVS around the pads PAD. Also, in some implementations, a chip edge region may be located outside the pad region PR. Also, some of the scribe lanes may remain in the chip edge region.

In the first substrate 1 of the pixel array region APS and the light-blocking region OB, a deep trench isolation DTI may separate the unit pixels UP from each other. As shown in FIG. 5, the deep trench isolation DTI may also be formed in the contact region BR1 and the back-side via region BR2 of the peripheral region PE. The deep trench isolation DTI may have a mesh shape in a plan view. The deep trench isolation DTI may have a structure that passes through the first substrate 1 in the vertical direction (the z direction). As the deep trench isolation DTI has a structure passing through the first substrate 1, crosstalk caused by light obliquely incident on the image sensor 1000 may be prevented.

The deep trench isolation DTI may be located inside a deep trench 22. In some implementations, the deep trench isolation DTI may have a front DTI (FDTI) structure that extends from the front side 1a to the back side 1b of the first substrate 1. In some implementations, the deep trench isolation DTI may have a back DTI (BDTI) structure that extends from the back side 1b to the front side 1a of the first substrate 1. For reference, the FDTI structure and the BDTI structure may be identified by the width of each of the front side 1a and the back side 1b. The deep trench isolation DTI may be formed by forming a trench in the first substrate 1 and filling the inside of the trench with an insulating material and a conductive material. Accordingly, in the FDTI structure in which the trench is formed from the front side 1a, the width of the front side 1a may be greater than the width of the back side 1b. On the contrary, in the BDTI structure in which the trench is formed from the back side 1b, the width of the back side 1b may be greater than the width of the front side 1a.

The deep trench isolation DTI may include an insulating pattern 12, a side insulating layer 14, and a conductive pattern 16. The insulating pattern 12 may be located between the conductive pattern 16 and a first interlayer insulating layer IL1. The side insulating layer 14 may be located between the conductive pattern 16 and the first substrate 1 and between the insulating pattern 12 and the first substrate 1. The side insulating layer 14 may surround the outside of the conductive pattern 16 and insulate the conductive pattern 16 from the first substrate 1. For example, the side insulating layer 14 may include silicon oxide, silicon nitride, and/or silicon oxynitride.

The insulating pattern 12 and the side insulating layer 14 may include an insulating material having a different refractive index than the first substrate 1. For example, the insulating pattern 12 and the side insulating layer 14 may include silicon oxide. The conductive pattern 16 may be spaced apart from the first substrate 1 by the side insulating layer 14. The conductive pattern 16 may include polysilicon or silicon germanium doped with impurities. The impurity doped into the polysilicon or the silicon germanium may include, for example, one of boron, phosphorus, and arsenic. For example, the conductive pattern 16 may include metal, metal silicide, and/or metal-containing conductive materials.

The photodiode PD may be doped with second conductivity-type impurities having opposite characteristics to the first conductivity-type impurities. For example, the second conductivity-type may represent an N type. A region doped with the N-type impurities may form PN junction with the first substrate 1 doped with the P-type impurities, thereby constituting the photodiode PD.

A shallow trench isolation STI may be located adjacent to the front side 1a of the first substrate 1. The shallow trench isolation STI may be penetrated by the deep trench isolation DTI. In some implementations, the image sensor 1000 may have a structure in which the deep trench isolation DTI is in contact with the shallow trench isolation STI. Active regions may be defined inside the unit pixel UP by the shallow trench isolation STI. The transistors (e.g., TX, RX, DX, and SX) of the unit pixel UP may be arranged in the active regions.

A transfer gate TG of the transfer transistor TX of the unit pixel UP may be located on the front side 1a of the first substrate 1. The transfer gate TG may have a vertical gate structure in which the transfer gate TG partially extends into the first substrate 1. In some implementations, the transfer gate TG may have a planar gate structure in which the transfer gate TG is disposed only on the front side of the first substrate 1. A gate insulating layer Gox may be located between the transfer gate TG and the first substrate 1. The floating diffusion region FD may be located inside the first substrate 1 on one side of the transfer gate TG. The floating diffusion region FD may be doped with, for example, second conductivity-type impurities.

The image sensor 1000 according to the inventive concept may include an image sensor having a back-side illumination (BSI) structure. The BSI structure may represent a structure in which a color filter CF and a meta-microlens array MLA are arranged on the back side 1b of the first substrate 1, and a first wire layer 130 is arranged on the front side 1a of the first substrate 1. Accordingly, in the image sensor 1000, light may be incident on the photodiode PD of the pixel array region APS via the back side 1b of the first substrate 1. Electron-hole pairs may be generated in the photodiode PD by the light incident on the photodiode PD, and electrons may be accumulated. Subsequently, when the transfer transistor TX is turned on, the electrons accumulated in the photodiode PD may move to the floating diffusion region FD.

A first unit pixel UP(1) and a second unit pixel UP(2) may be arranged in the light-blocking region OB of the first substrate 1. A black photodiode PD′ may be provided inside the first substrate 1 in the first unit pixel UP(1). A dummy photodiode PD″ may be provided inside the first substrate 1 in the second unit pixel UP(2). For example, the black photodiode PD′ may be doped with the second conductivity-type impurities different from the first conductivity-type impurities. For example, the second conductivity-type may represent an N type. The black photodiode PD′ may have a similar structure to the photodiode PD, but may not perform an operation of the photodiode PD (i.e., an operation of receiving light and generating an electrical signal). Since light is blocked in the black photodiode PD′, the black photodiode PD′ may generate a dark level reference signal. The signal processing unit 700 of FIG. 1 may compensate for a dark level of output values of the pixels of the pixel array region APS by using the dark level reference signal. The dummy photodiode PD″ may not be doped with impurities. A signal generated from the dummy photodiode PD″ may be used as information to remove subsequent process noise.

The first semiconductor chip CH1 may include the first wire layer 130 that is disposed on the front side 1a of the first substrate 1. The first wire layer 130 may include the first interlayer insulating layer IL1, a first wire line 15, and a first via contact 17. The first interlayer insulating layer IL1 may have a multi-layer structure and include at least one of silicon oxide, silicon nitride, silicon oxynitride, and a porous low-k dielectric material. The first wire line 15 may be located inside the first interlayer insulating layer IL1. The first wire line 15 may have a multi-layer structure corresponding to the multi-layer structure of the first interlayer insulating layer IL1. First wire lines 15 on different layers may be connected to each other by the first via contact 17 that at least partially passes through the first interlayer insulating layer IL1. Also, the first wire line 15 may be connected to the floating diffusion region FD and the transfer gate TG via the first via contact 17.

An anti-reflection structure AL may be arranged on the back side 1b of the first substrate 1. The anti-reflection structure AL may be disposed throughout the pixel region PA and the peripheral region PE. However, the anti-reflection structure AL may not be arranged on the back-side contact BCA, the back-side via BVS, and the pad PAD. The anti-reflection structure AL may include a first insulating layer A1, a second insulating layer A2, a third insulating layer A3, and a fourth insulating layer A4, which are sequentially stacked on one another. Each of the first to fourth insulating layers A1, A2, A3, and A4 may include aluminum oxide, silicon oxide, and/or hafnium oxide. In some implementations, the first insulating layer A1 and the third insulating layer A3 may include the same material, but the present disclosure is not limited thereto.

A grid pattern 120 may be disposed on the anti-reflection structure AL of the pixel array region APS. The grid pattern 120 may have a mesh shape in a plan view and overlap the deep trench isolation DTI in the vertical direction (the z direction). The grid pattern 120 may have uniform width and thickness and include organic and/or inorganic materials of a low refractive index. Here, the width may represent a width in the x direction or the y direction, and the thickness may represent a thickness in the z direction.

For reference, the low refractive index and high refractive index may be determined based on a refractive index of about 1.5. For example, TiO₂, which is known to have the highest refractive index among metal oxides, may have a very high refractive index of 2.5 (anatase crystal) or 2.7 (rutile crystal). On the other hand, MgF₂ may have a low refractive index of about 1.38. Also, MgF₂ may have a porous structure as the angle of oblique incidence increases, resulting in a decrease in the refractive index, and may exhibit a very low refractive index of about 1.2 at oblique incidence of 80°.

The grid pattern 120 may include a light-blocking grid pattern 48a and a low-refractive grid pattern 50a. For example, the light-blocking grid pattern 48a may include titanium and/or titanium nitride. The low-refractive grid pattern 50a may include an insulating layer. In some implementations, the grid pattern 120 may include a single insulating layer structure. In some implementations, the grid pattern 120 may include a multi-insulating layer structure.

Color filters CF1 and CF2 may be arranged inside grids of the grid pattern 120 on the anti-reflection structure AL. That is, the color filters CF1 and CF2 may be separated from each other by the grid pattern 120. The color filters CF1 and CF2 may have, for example, one color of blue, green, and red. In some implementations, the color filters CF1 and CF2 may include color combinations, such as cyan, magenta, and yellow. In the image sensor 1000, the color filters CF1 and CF2 may be arranged in a Bayer pattern. However, in some implementations, the color filters CF1 and CF2 may be arranged in a tetra pattern of 2×2 arrangement, a nona pattern of 3×3 arrangement, or a hexadeca pattern of 4×4 arrangement.

A light-blocking layer may be disposed on the anti-reflection structure AL in the light-blocking region OB of the first substrate 1. The light-blocking layer may block light that is incident on the black photodiode PD′ and the dummy photodiode PD″ formed in the first substrate 1 of the light-blocking region OB.

The light-blocking layer may include a first light-blocking layer 52p and a second light-blocking layer CFB. The first light-blocking layer 52p may include titanium, titanium nitride, and/or tungsten. The second light-blocking layer CFB may include a blue color filter.

A barrier metal BM may be located between the first light-blocking layer 52p and the anti-reflection structure AL. For example, the barrier metal BM may include titanium and/or titanium nitride. In addition, the barrier metal BM may be located between first to third conductive patterns 52a, 52b, and 52c and the anti-reflection structure AL.

The back-side contacts BCA may be arranged in the contact region BR1. The back-side contact BCA may pass through the anti-reflection structure AL and be located inside a first trench 46 of the first substrate 1. The back-side contact BCA may include the first conductive pattern 52a and a first metal pattern 54a. In the back-side contact BCA, the first conductive pattern 52a and the barrier metal BM may conformally cover the sidewall and the bottom surface inside the first trench 46.

For example, the first metal pattern 54a may include aluminum. However, the material of the first metal pattern 54a is not limited to aluminum. The first metal pattern 54a may fill the first trench 46. The back-side contact BCA may be connected to the conductive pattern 16 of the deep trench isolation DTI. The back-side contact BCA may receive a certain voltage, such as a ground voltage or a negative voltage, via the first conductive pattern 52a and apply the voltage to the conductive pattern 16 of the deep trench isolation DTI. As described above, the ground or negative voltage may be applied to the conductive pattern 16 of the deep trench isolation DTI via the back-side contact BCA, and holes that may exist on the surface of the side insulating layer 14 of the deep trench isolation DTI may be fixed, thereby improving dark current characteristics.

In the back-side via region BR2, the first back-side vias BVS(1) may be arranged. The first back-side vias BVS(1) may be located in first holes H1. The first back-side vias BVS(1) may extend in the vertical direction (the z direction), and may pass through the anti-reflection structure AL, the first substrate 1, and the first interlayer insulating layer IL1 and may partially pass through a second interlayer insulating layer IL2. In the first back-side vias BVS(1), the second conductive pattern 52b and the barrier metal BM may conformally cover the sidewall and the bottom surface of the first hole H1.

The first back-side vias BVS(1) may electrically connect some of the first wire lines 15 of the first semiconductor chip CH1 to some of second wire lines 172 of the second semiconductor chip CH2 via the second conductive pattern 52b. Also, the first hole H1 may be filled with a first protective pattern 50b. For example, the first protective pattern 50b may include a material having a low refractive index. Also, a capping pattern CFR may be disposed on the first protective pattern 50b.

In the pad region PR, the pad PAD may be located. The pad PAD may be located inside a second trench 60. The PAD may include a third conductive pattern 52c and a second metal pattern 54b. In the pad PAD, the third conductive pattern 52c and the barrier metal BM may conformally cover the side surface and the bottom surface of the second trench 60.

For example, the second metal pattern 54b may include aluminum. However, the material of the second metal pattern 54b is not limited to aluminum. The second metal pattern 54b may fill the second trench 60.

In FIG. 4, the second back-side vias BVS(2) may be arranged around the pad PAD. Like the first back-side vias BVS(1), the second back-side vias BVS(2) may pass through the anti-reflection structure AL, the first substrate 1, and the first interlayer insulating layer IL1, and may partially pass through the second interlayer insulating layer IL2. The second back-side vias BVS(2) may not be connected to the first wire lines 15, but may be connected to some of the second wire lines 172. In the second back-side vias BVS(2), the third conductive pattern 52c and the barrier metal BM may conformally cover the sidewall and the bottom surface of the second hole H2.

The second back-side vias BVS(2) may electrically connect some of the second wire lines 172 of the second semiconductor chip CH2 via the third conductive pattern 52c. Also, the second hole H2 may be filled with a second protective pattern 50c. For example, the second protective pattern 50c may include a material having a low refractive index. Also, the capping pattern CFR may be disposed on the second protective pattern 50c.

The second back-side vias BVS(2) may be connected to the pad PAD corresponding thereto via the third conductive pattern 52c. That is, signals input from outside the image sensor 1000 or output from the image sensor 1000 may be interfaced by the second back-side vias BVS(2) and the pad PAD.

The first conductive pattern 52a, the second conductive pattern 52b, the third conductive pattern 52c, and the first light-blocking layer 52p are distinguishably classified only for convenience of description and may include the same material.

In the pad region PR, an opening 35 may pass through a planarization layer 70, the meta-microlens array MLA, and an anti-reflection layer 90 to expose the pad PAD.

The second semiconductor chip CH2 may include a second substrate 2 and a second wire layer 170. The second semiconductor chip CH2 may be disposed below the first semiconductor chip CH1, and the second wire layer 170 of the second semiconductor chip CH2 may be coupled to the first wire layer 130 of the first semiconductor chip CH1. The second substrate 2 may be substantially the same as the first substrate 1.

Transistors PTR for logic elements may be arranged on the second substrate 2. A transistor PTR for logic elements may constitute the circuit blocks (e.g., 200 to 700) of the image sensor 1000. In the second semiconductor chip CH2, the upper surface of the second substrate 2 may correspond to the front side that is the active surface. Also, the second wire layer 170 may be disposed on the second substrate 2 and the transistor PTR. The second wire layer 170 may include the second interlayer insulating layer IL2, a second wire line 172, and a second via contact 174. The second interlayer insulating layer IL2, the second wire line 172, and the second via contact 174 may be substantially the same as the first interlayer insulating layer IL1, the first wire line 15, and the first via contact 17 of the first wire layer 130, respectively.

The image sensor 1000 may further include a protective layer 56 that is disposed above the anti-reflection structure AL and covers the grid pattern 120, the first light-blocking layer 52p, the first conductive pattern 52a, the second conductive pattern 52b, and the third conductive pattern 52c. In the pixel array region APS, the protective layer 56 may surround and protect the outer peripheral surfaces of the color filters CF1 and CF2. The second light-blocking layer CFB may be disposed on the protective layer 56. For example, the protective layer 56 may include tetraethyl orthosilicate (TEOS).

The image sensor 1000 may include the planarization layer 70 that covers the color filters CF1 and CF2 and the second light-blocking layer CFB. The planarization layer 70 may be located between the first substrate 1 and the meta-microlens array MLA. The planarization layer 70 may extend from the pixel array region APS to the peripheral region PE. The planarization layer 70 may cover the protective layer 56. A first surface of the planarization layer 70 may be in contact with an etch stop layer ES. A second surface of the planarization layer 70 may be in contact with the color filters CF1 and CF2, the second light-blocking layer CFB, and the protective layer 56. The planarization layer 70 may provide a flat surface for forming the meta-microlens array MLA. In some implementations, the planarization layer 70 may be in contact with the upper surface of the second light-blocking layer CFB and the side surface of the second light-blocking layer CFB. In some implementations, the planarization layer 70 may be in contact with the color filters CF1 and CF2.

In some implementations, the planarization layer 70 may include an inorganic material. For example, the planarization layer 70 may include oxide. For example, the planarization layer 70 may include silicon oxide, silicon nitride, and/or silicon oxynitride. For example, the planarization layer 70 may include a material that is easily processed at about 250° C. or less. The planarization layer 70 may be formed by a chemical vapor deposition (CVD) method and/or a coating method.

A first thickness T 1 of the planarization layer 70 may be about 300 nm to about 1000 nm. The first thickness T 1 of the planarization layer 70 may represent the distance from the upper surfaces of the color filters CF1 and CF2 to the upper surface of the planarization layer 70 in the vertical direction (the z direction). In addition, the distance from the upper surface of the second light-blocking layer CFB to the upper surface of the planarization layer 70 in the vertical direction (the z direction) may be in a range of about 300 nm to about 1000 nm. A second thickness T2, which is the thickness from the upper surface of the protective layer 56 to the upper surface of the planarization layer 70, may be in a range of about 500 nm to about 2000 nm. That is, the thickness from the lowermost surface of the planarization layer 70 to the upper surface of the planarization layer 70 may be in a range of about 500 nm to about 2000 nm.

The etch stop layer ES may be disposed on the planarization layer 70. The etch stop layer ES may protect the planarization layer 70 from damage during a process of forming a nanopost NP. Accordingly, the etch stop layer ES may be located between the planarization layer 70 and the meta-microlens array MLA.

For example, the etch stop layer ES may include aluminum oxide, hafnium oxide, and/or silicon nitride. In some implementations, the etch stop layer ES may have a thickness of about 3 nm to about 50 nm, or about 5 nm to about 15 nm.

FIG. 5 illustrates that the etch stop layer ES completely covers the upper surface of the planarization layer 70, but the present disclosure is not limited thereto. For example, the etch stop layer ES may only partially cover the upper surface of the planarization layer 70. For example, the etch stop layer ES may be disposed only below the nanopost NP. In this case, the upper surface of the planarization layer 70 may be partially in contact with a dielectric layer DL.

The image sensor 1000 may further include the meta-microlens array MLA. The meta-microlens array MLA may be supported by the planarization layer 70. The meta-microlens array MLA may split incident light according to wavelengths and/or provide incident light to each of a plurality of photodiodes PD. To this end, the meta-microlens array MLA may include a plurality of nanoposts NP arranged in a certain meta-pattern and the dielectric layer DL filling spaces between the plurality of nanoposts NP.

The nanoposts NP may be arranged such that the phase of transmissive light passing through the meta-microlens array MLA varies according to locations on the meta-microlens array MLA. Depending on the width (or diameter) and height of each of the nanoposts NP and on the arrangement intervals (or pitches) and arrangement forms of the plurality of nanoposts NP, a phase profile of the transmissive light formed by the meta-microlens array MLA may be determined. In addition, the behavior of light transmitted through the meta-microlens array MLA may be determined by the phase profile of the transmissive light. For example, the plurality of nanoposts NP may be arranged to form a phase distribution in which light transmitted through the meta-microlens array MLA is focused.

The nanopost NP may have a size smaller than the wavelength of visible light. For example, the nanopost NP may have a size smaller than the wavelength of blue light. For example, the cross-sectional width (or diameter) of the nanopost NP may be less than 400 nm, 300 nm, or 200 nm. The height of the nanopost NP may be about 500 nm to about 1500 nm, and the height may be greater than the width on the cross-section.

The nanopost NP may include a material having a high refractive index that changes the phase of incident light. The dielectric layer DL may be located between the plurality of nanoposts NP and include a material having a refractive index lower than the refractive index of the nanopost NP. For example, the nanopost NP may include crystalline silicon (c-Si), polycrystalline silicon (p-Si), amorphous silicon (a-Si), group III-V compound semiconductors (GaP, GaN, GaAs, etc.), SiC, TiO₂, SiN₃, ZnS, ZnSe, Si₃N₄, and/or a combination thereof. For example, the dielectric layer DL may include a siloxane-based spin on glass (SOG), silicon oxide, silicon nitride, aluminum oxide, and/or air.

FIG. 5 shows that plurality of nanoposts NP have the same diameter and are spaced apart from each other by the same interval, but the present disclosure is not limited thereto. For example, at least two of the plurality of nanoposts NP may have different diameters. Also, the distances between the plurality of nanoposts NP in the horizontal direction (x direction and/or y direction) may be different from each other.

In the peripheral region PE, the meta-microlens array MLA may not include a nanopost NP. FIG. 5 shows an example in which the nanoposts NP are arranged in the pixel array region APS and the light-blocking region OB, but the inventive concept is not limited thereto. In some implementations, the nanoposts NP may be arranged only in the pixel array region APS.

The anti-reflection layer 90 may be disposed on the meta-microlens array MLA. That is, the meta-microlens array MLA may be located between the etch stop layer ES and the anti-reflection layer 90. The anti-reflection layer 90 may cover at least partially the meta-microlens array MLA in a region in which the nanoposts NP are formed, and may completely cover the front side of the meta-microlens array MLA in a region in which the nanoposts NP are not formed. In other words, the anti-reflection layer 90 may at least partially cover the meta-microlens array MLA in the pixel array region APS and the light-blocking region OB, and may cover the front side of the meta-microlens array MLA in the peripheral region PE.

In the pixel array region APS and the light-blocking region OB, the anti-reflection layer 90 may be formed in patterns. For example, in the pixel region PA, the anti-reflection layer 90 may have a structure with holes. The holes may be exposed to the outside. The holes may be arranged in a two-dimensional grid pattern. The cross-sectional areas of the holes in the horizontal direction (the x direction and/or the y direction) may be constant. The anti-reflection layer 90 may include a material having a refractive index different from the refractive index of the meta-microlens array MLA. In some implementations, the refractive index of the anti-reflection layer 90 may be greater than the refractive index of air and less than the refractive index of the meta-microlens array MLA.

FIG. 5 shows an example in which the anti-reflection layer 90 is formed as a single layer, but the present disclosure is not limited thereto. For example, the anti-reflection layer 90 may be formed as a plurality of layers.

In the image sensor 1000, the planarization layer 70 in contact with the color filters CF1 and CF2 and the second light-blocking layer CFB may include an inorganic material and thus reduce the size of stepped regions formed by the color filters CF1 and CF2 and the second light-blocking layer CFB. Accordingly, the meta-microlens array MLA may be easily formed on the planarization layer 70. Accordingly, the formation of the meta-microlens array MLA is facilitated, and thus, the image sensor 1000 may be easily formed.

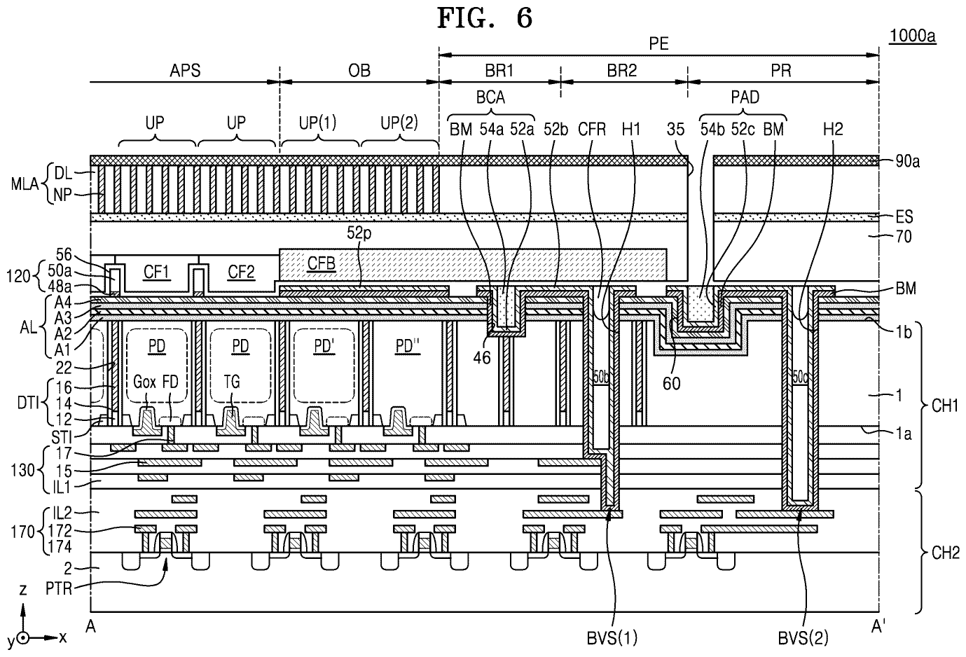

FIG. 6 is a cross-sectional view of an example of an image sensor 1000a in an area corresponding to a cross-section taken along line A-A′ of FIG. 4 according to some implementations.

The image sensor 1000a of FIG. 6 may be substantially the same as the image sensor 1000 of FIG. 5, except that the image sensor 1000a includes an anti-reflection layer 90a. Accordingly, the image sensor 1000a is described herein primarily in terms of the anti-reflection layer 90a.

In FIG. 6, the image sensor 1000a may include the anti-reflection layer 90a that completely covers the upper surface of the meta-microlens array MLA. The anti-reflection layer 90a may include a material having a refractive index different from the refractive index of the meta-microlens array MLA. In some implementations, the refractive index of the anti-reflection layer 90a may be greater than the refractive index of air and less than the refractive index of the meta-microlens array MLA. For example, the anti-reflection layer 90a may include a material having a low refractive index. For example, the anti-reflection layer 90a may include a material having a refractive index of about 1.5 or less. For example, the anti-reflection layer 90a may include a material having a refractive index of about 1.3 or less. For example, the anti-reflection layer 90a may include silicon oxide.

FIG. 6 shows an example in which the anti-reflection layer 90a is formed as a single layer, but the present disclosure is not limited thereto. For example, the anti-reflection layer 90a may be formed as a plurality of layers.

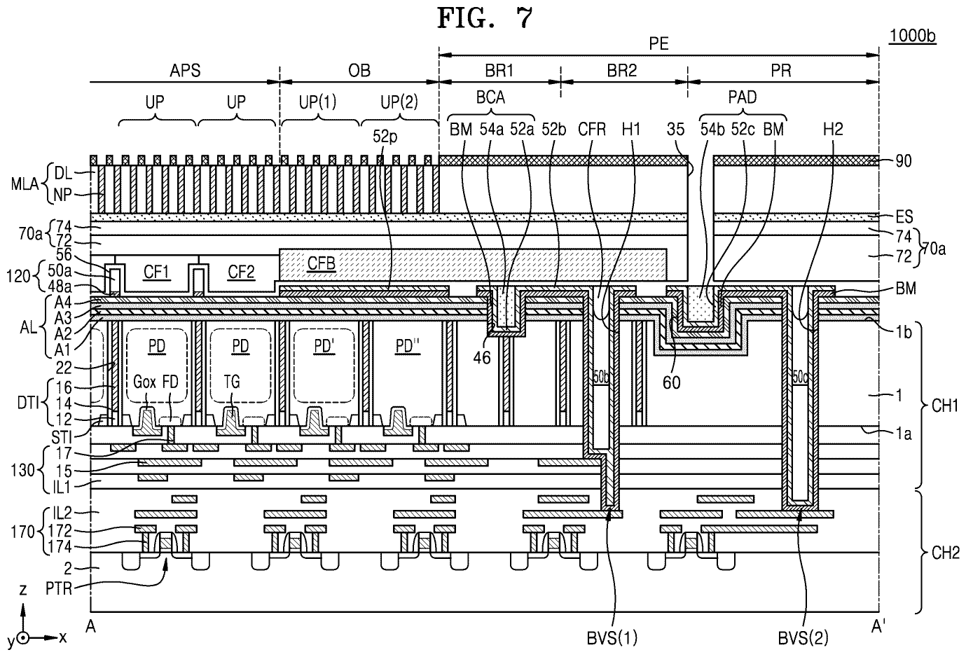

FIG. 7 is a cross-sectional view of an example of an image sensor 1000b in an area corresponding to a cross-section taken along line A-A′ of FIG. 4 according to some implementations.

The image sensor 1000b of FIG. 7 may be substantially the same as the image sensor 1000 of FIG. 5, except that the image sensor 1000b includes a planarization layer 70a. Accordingly, the image sensor 1000b is described herein primarily in terms of the planarization layer 70a.

In FIG. 7, the image sensor 1000b may include the planarization layer 70a that is located between the color filters CF1 and CF2 and the etch stop layer ES. The planarization layer 70a may include a first planarization layer 72 and a second planarization layer 74. The second planarization layer 74 may be stacked on the first planarization layer 72. The first planarization layer 72 and the second planarization layer 74 may include inorganic materials. For example, the first planarization layer 72 and the second planarization layer 74 may include oxide. For example, the first planarization layer 72 and the second planarization layer 74 may include silicon oxide, silicon nitride, and/or silicon oxynitride. For example, the first planarization layer 72 and the second planarization layer 74 may include a material that is easily processed at about 250° C. or less. The first planarization layer 72 and the second planarization layer 74 may be formed by a CVD method or a coating method. When the planarization layer 70a includes a plurality of layers, the reflectance of light incident on the image sensor 1000b may be improved.

FIG. 7 shows an example in which the planarization layer 70a includes two layers, but the present disclosure is not limited thereto. For example, the planarization layer 70a may include three or more layers.

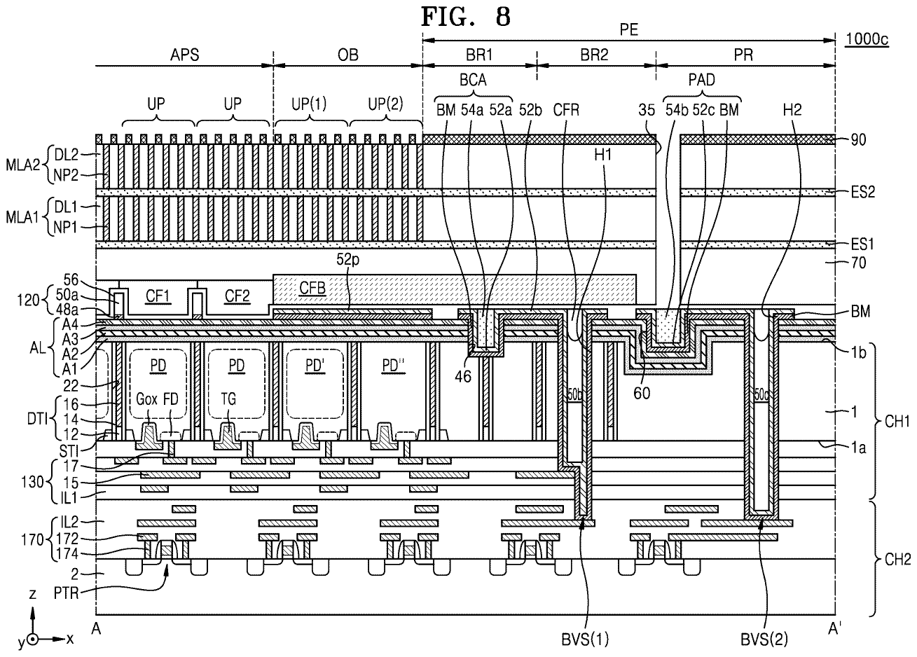

FIG. 8 is a cross-sectional view of an example of an image sensor 1000c in an area corresponding to a cross-section taken along line A-A′ of FIG. 4 according to some implementations.

The image sensor 1000c of FIG. 8 may be substantially the same as the image sensor 1000 of FIG. 5, except that the image sensor 1000c includes a first meta-microlens array MLA1 and a second meta-microlens array MLA2. Accordingly, the image sensor 1000c is described herein primarily in terms of the first meta-microlens array MLA1 and the second meta-microlens array MLA2.

In FIG. 8, a first etch stop layer ES1 may be disposed on the planarization layer 70, and the first meta-microlens array MLA1 may be disposed on the first etch stop layer ES1. The first etch stop layer ES1 may be substantially the same as the etch stop layer ES of FIG. 5. Also, the first meta-microlens array MLA1 may include a first nanopost NP1 and a first dielectric layer DL1. The first meta-microlens array MLA1 may be substantially the same as the meta-microlens array MLA of FIG. 5.

The second meta-microlens array MLA2 may be disposed above the first meta-microlens array MLA1. The second meta-microlens array MLA2 may include a second nanopost NP2 and a second dielectric layer DL2. The second nanopost NP2 may be substantially the same as the first nanopost NP1, and the second dielectric layer DL2 may be substantially the same as the first dielectric layer DL1.

The incident light incident on the image sensor 1000c may pass through the second meta-microlens array MLA2 and then pass through the first meta-microlens array MLA1. The thickness of the first meta-microlens array MLA1 may be substantially the same as the thickness of the second meta-microlens array MLA2.

FIG. 8 shows an example in which a plurality of first nanoposts NP1 are respectively aligned with a plurality of second nanoposts NP2 in the vertical direction (the z direction), but the present disclosure is not limited thereto. For example, the plurality of first nanoposts NP1 may be different from the plurality of second nanoposts NP2 in terms of locations in the horizontal direction (the x direction and/or the y direction).

A second etch stop layer ES2 may be located between the first meta-microlens array MLA1 and the second meta-microlens array MLA2. The second etch stop layer ES2 may include the same material as the first etch stop layer ES1.

An anti-reflection layer 90 may be disposed on the second meta-microlens array MLA2. The anti-reflection layer 90 may be substantially the same as the anti-reflection layer 90 of FIG. 5.

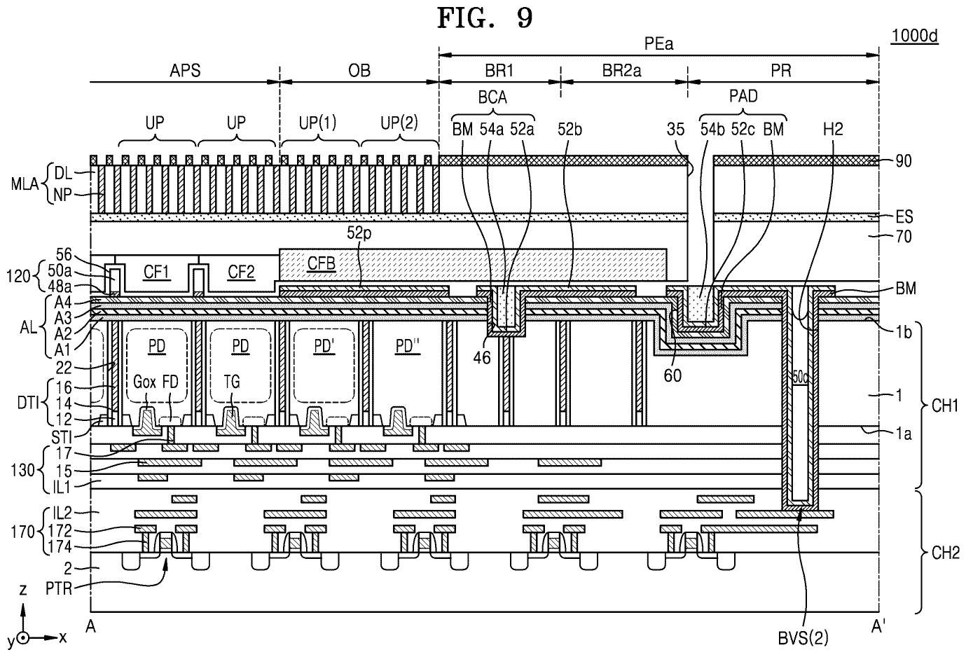

FIG. 9 is a cross-sectional view of an example of an image sensor 1000d in an area corresponding to a cross-section taken along line A-A′ of FIG. 4 according to some implementations.

The image sensor 1000d of FIG. 9 may be substantially the same as the image sensor 1000 of FIG. 5, except that the image sensor 1000d does not include the first back-side vias BVS(1). Accordingly, the image sensor 1000d is described herein primarily in terms of a back-side via region BR2a.

In FIG. 9, the image sensor 1000d may not include the first back-side vias BVS(1) in the back-side via region BR2a. When the first back-side vias BVS(1) are omitted, the first light-blocking layer 52p may have a simple shape, which may reduce stepped regions of the first conductive pattern 52a. Accordingly, stepped regions in the second light-blocking layer CFB above the first conductive pattern 52a may be reduced. Accordingly, before forming the meta-microlens array MLA, the meta-microlens array MLA may be easily formed due to a reduction in the stepped region of a semiconductor device.

Also, the back-side contacts BCA in the contact region BR1 and the second back-side vias BVS(2) in the pad region PR may not be omitted. In some implementations, the back-side contacts BCA of the contact region BR1 and/or the second back-side vias BVS(2) in the pad region PR may also be omitted.

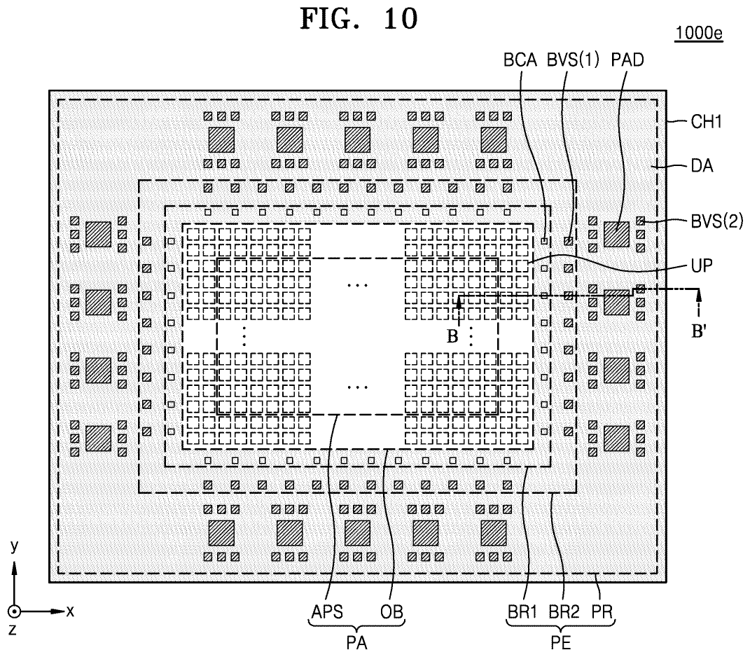

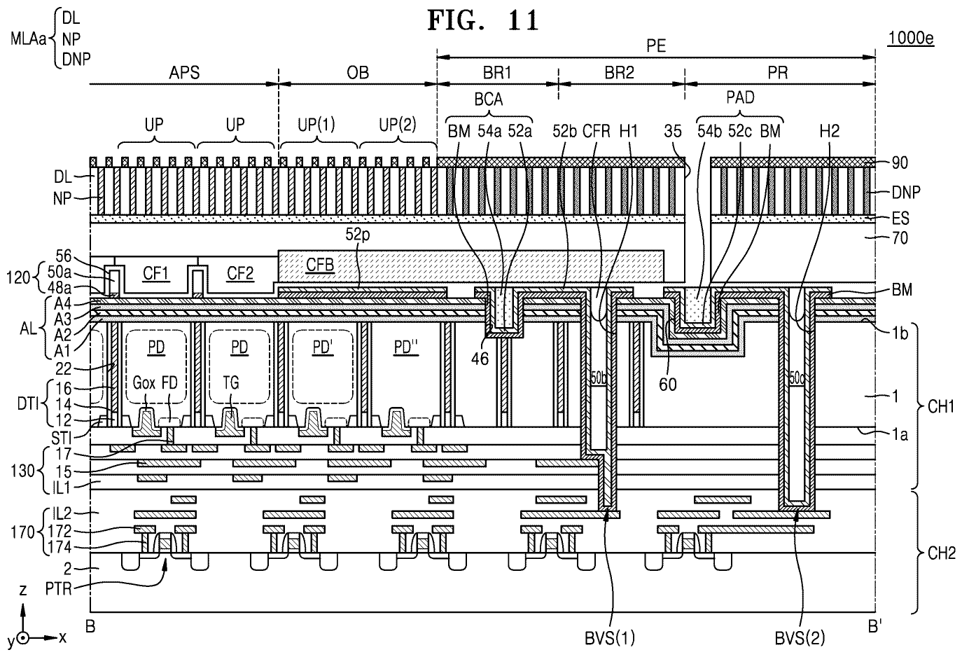

FIG. 10 is a plan view of an example of an image sensor 1000e corresponding to the image sensor 1000 of FIG. 1 according to some implementations, and FIG. 11 is a cross-sectional view of the image sensor 1000e taken along line B-B′ of FIG. 10 according to some implementations. A description is given below with reference to FIGS. 4 and 5 together.

The image sensor 1000e of FIG. 10 may be substantially the same as the image sensor 1000 of FIG. 4, except that the image sensor 1000e includes a dummy region DA. Also, the image sensor 1000e of FIG. 11 may be substantially the same as the image sensor 1000 of FIG. 5, except that the image sensor 1000e includes a meta-microlens array MLAa. Accordingly, the image sensor 1000e is described herein primarily in terms of the dummy region DA and the meta-microlens array MLAa.

In FIGS. 10 and 11, the dummy region DA may be formed outside of the light-blocking region OB. The dummy region DA may represent a region in which a dummy nanopost DNP is located.

The image sensor 1000e may include the meta-microlens array MLAa above the planarization layer 70. The meta-microlens array MLAa may include the nanopost NP, the dielectric layer DL, and the dummy nanopost DNP. The nanopost NP and the dielectric layer DL of the meta-microlens array MLAa may be substantially the same as the nanopost NP and the dielectric layer DL of the meta-microlens array MLA of FIG. 5.

The dummy nanopost DNP may be located in the peripheral region PE. The dummy nanopost DNP may improve the structural reliability of the meta-microlens array MLAa. The dummy nanopost DNP may reduce stepped regions of the meta-microlens array MLAa, thereby planarizing the meta-microlens array MLAa.

The thickness of the dummy nanopost DNP may be substantially the same as the thickness of the meta-microlens array MLAa. The dummy nanopost DNP may include the same material as the nanopost NP.

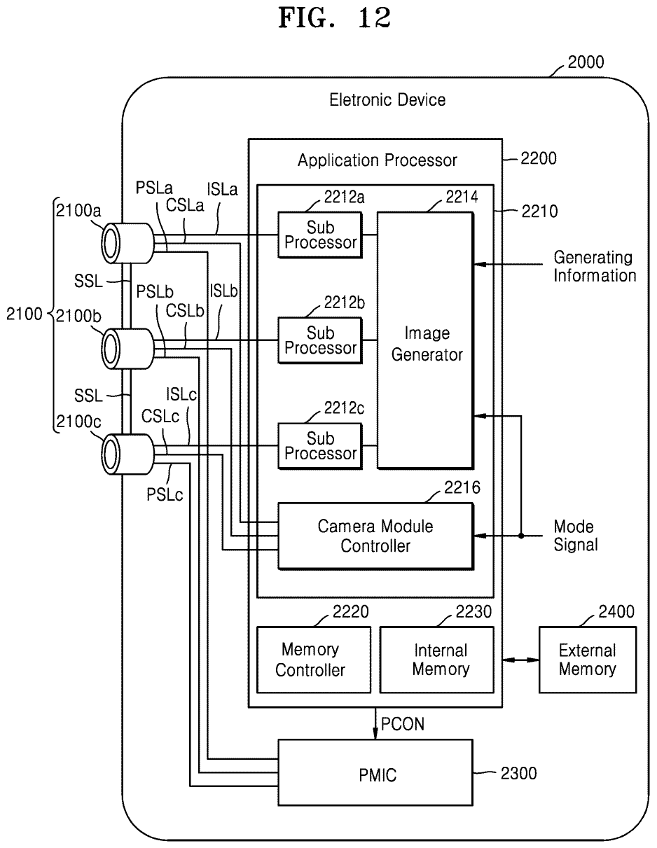

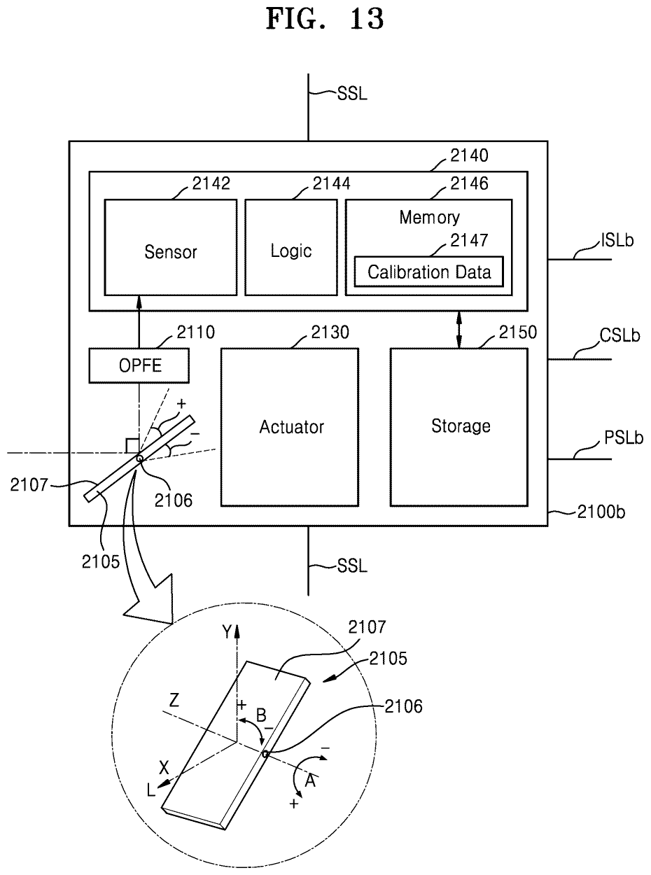

FIG. 12 is a block diagram of an example of an electronic device 2000 including a multi-camera module according to some implementations. FIG. 13 is a detailed block diagram of a camera module of FIG. 12 according to some implementations.

In FIG. 12, the electronic device 2000 may include a camera module group 2100, an AP 2200, a power management integrated circuit (PMIC) 2300, and storage 2400.

The camera module group 2100 may include a plurality of camera modules 2100a, 2100b, and 2100c. Although the diagram illustrates an implementations in which three camera modules 2100a, 2100b, and 2100c are arranged, some implementations are not limited thereto. In some implementations, the camera module group 2100 may include only two camera modules or may be modified to include n camera modules (where n is a natural number greater than or equal to 4).

In FIG. 13, the camera module 2100b may include a prism 2105, an optical path folding element (OPFE) 2110, an actuator 2130, an image sensing device 2140, and storage 2150.

Here, the detailed configuration of the camera module 2100b is described in more detail, but the following description may equally apply to the other camera modules 2100a and 2100c according to some implementations.

The prism 2105 includes a reflective surface 2107 of a light-reflecting material and may change a path of light L incident from the outside.

In some implementations, the prism 2105 may change the path of light L incident in a first direction (an X direction) to a second direction (a Y direction) perpendicular to the first direction (the X direction). In addition, the prism 2105 may rotate the reflective surface 2107 of the light-reflecting material in a direction A about a central axis 2106 or rotate the central axis 2106 in a direction B and may change the path of light L incident in the first direction (the X direction) to the second direction (the Y direction) perpendicular thereto. In this case, the OPFE 2110 may also move in the first direction (the X direction), the second direction (the Y direction), and a third direction (a Z direction).

In some implementations, as illustrated in the diagram, the maximum rotation angle of the prism 2105 in the direction A may be less than or equal to 15° (degrees) in a positive (+) direction A and greater than 15° in a negative (−) direction A. However, the present disclosure is not limited thereto.

In some implementations, the prism 2105 may move, in a positive (+) or negative (−) direction B, by about 20°, between about 10° and about 20°, or between about 15° and about 20°. Herein, the angles of movement may be equal to each other in the positive (+) direction B and the negative (−) direction B, or be nearly equal to each other within a range of about 1°.

In some implementations, the prism 2105 may move the reflective surface 2107 of the light-reflecting material in the third direction (the Z direction) parallel to the direction in which the central axis 2106 extends.

The OPFE 2110 may include, for example, optical lenses including m groups (where m is a natural number). The m lenses may be moved in the second direction (the Y direction) to change an optical zoom ratio of the camera module 2100b. For example, when a basic optical zoom ratio of the camera module 2100b is Z, if the m optical lenses of the OPFE 2110 move, the optical zoom ratio of the camera module 2100b may be changed to 3Z or higher.

The actuator 2130 may move the OPFE 2110 or the optical lens to specific positions. For example, the actuator 2130 may adjust the position of the optical lens so that an image sensor 2142 is located at a focal length of the optical lens in order to achieve accurate sensing.

The image sensing device 2140 may include the image sensor 2142, a control logic 2144, and memory 2146. The image sensor 2142 may sense an image of an object to be sensed, by using the light L provided via the optical lens. The control logic 2144 may control all operations of the camera module 2100b. For example, the control logic 2144 may control the operation of the camera module 2100b according to a control signal provided via a control signal line CSLb.

The memory 2146 may store information, such as calibration data 2147, necessary for the operation of the camera module 2100b. The calibration data 2147 may include information that is necessary for the camera module 2100b to generate image data by using the light L provided from the outside. The calibration data 2147 may include, for example, information about the degree of rotation, information about the focal length, and information about the optical axis, which are described above. When the camera module 2100b is provided as a multi-state camera in which a focal length varies depending on the position of an optical lens, the calibration data 2147 may include a focal length value for each position (or state) of the optical lens and information about autofocus.

The storage 2150 may store image data sensed by the image sensor 2142. The storage 2150 may be located outside the image sensing device 2140 and provided while being stacked with a sensor chip that constitutes the image sensing device 2140. In some implementations, the storage 2150 may be provided as electrically erasable programmable read-only memory (EEPROM), but the present disclosure is not limited thereto.

In FIGS. 12 and 13, each of the plurality of camera modules 2100a, 2100b, and 2100c may include the actuator 2130. Accordingly, the plurality of camera modules 2100a, 2100b, and 2100c may include the same calibration data 2147 or different pieces of calibration data 2147, depending on the operations of the actuators 2130 respectively provided therein.

In some implementations, one camera module (e.g., 2100b) among the plurality of camera modules 2100a, 2100b, and 2100c may include a folded lens-type camera module that includes the prism 2105 and the OPFE 2110 described above, and the other camera modules (e.g., 2100a and 2100c) may include a vertical camera module that does not include the prism 2105 and the OPFE 2110. However, the present disclosure is not limited thereto.

In some implementations, one camera module (e.g., 2100c) among the plurality of camera modules 2100a, 2100b, and 2100c may include a vertical depth camera that extracts depth information by using, for example, infrared rays (IR). In this case, the AP 2200 may merge image data provided from the depth camera with image data provided from another camera module (e.g., 2100a or 2100b), thereby generating a 3D depth image.

In some implementations, at least two camera modules (e.g., 2100a and 2100b) among the plurality of camera modules 2100a, 2100b, and 2100c may have different fields of view (viewing angles). In this case, for example, at least two camera modules (e.g., 2100a and 2100b) among the plurality of camera modules 2100a, 2100b, and 2100c may have different optical lenses, but the present disclosure is not limited thereto.

Also, in some implementations, the plurality of camera modules 2100a, 2100b, and 2100c may have different viewing angles. In this case, the optical lenses in the plurality of camera modules 2100a, 2100b, and 2100c may also be different from each other, but the present disclosure is not limited thereto.

In some implementations, the plurality of camera modules 2100a, 2100b, and 2100c may be physically separated from each other. That is, instead of a sensing region of one image sensor 2142 being divided and used by the plurality of camera modules 2100a, 2100b, and 2100c, the one image sensor 2142 may be independently provided inside each of the plurality of camera modules 2100a, 2100b, and 2100c.

In FIG. 12, the AP 2200 may include an image processing device 2210, a memory controller 2220, and internal memory 2230. The AP 2200 may be provided separately from the plurality of camera modules 2100a, 2100b, and 2100c. For example, the AP 2200 and the plurality of camera modules 2100a, 2100b, and 2100c may be provided separately from each other on separate semiconductor chips.

The image processing device 2210 may include a plurality of sub-image processors 2212a, 2212b, and 2212c, an image generator 2214, and a camera module controller 2216.

The image processing device 2210 may include a plurality of sub-image processors 2212a, 2212b, and 2212c in a number corresponding to the number of camera modules 2100a, 2100b, and 2100c.

Pieces of image data generated from the camera modules 2100a, 2100b, and 2100c may be provided to the corresponding sub-image processors 2212a, 2212b, and 2212c via separate image signal lines ISLa, ISLb, and ISLc, respectively. For example, the image data generated from the camera module 2100a may be provided to the sub-image processor 2212a via the image signal line ISLa, the image data generated from the camera module 2100b may be provided to the sub-image processor 2212b via the image signal line ISLb, and the image data generated from the camera module 2100c may be provided to the sub-image processor 2212c via the image signal line ISLc. Such image data transmission may be performed by using, for example, a camera serial interface (CSI) based on mobile industry processor interface (MIPI), but the present disclosure is not limited thereto.

In some implementations, a single sub-image processor may correspond to a plurality of camera modules. For example, the sub-image processor 2212a and the sub-image processor 2212c may not be separated from each other as illustrated in the diagram, but integrated into a single sub-image processor. Here, the image data provided from the camera module 2100a and the camera module 2100c may be selected by a selection element (e.g., a multiplexer) and then provided to the integrated sub-image processor.

The image data provided to each of the sub-image processors 2212a, 2212b, and 2212c may be provided to the image generator 2214. The image generator 2214 may generate an output image by using the image data provided from each of the sub-image processors 2212a, 2212b, and 2212c according to image generating information or a mode signal.

Specifically, the image generator 2214 may generate an output image by at least partially merging image data generated from the camera modules 2100a, 2100b, and 2100c having different viewing angles according to the image generating information or the mode signal. Also, the image generator 2214 may generate an output image by selecting any one piece of image data generated from the camera modules 2100a, 2100b, and 2100c having different viewing angles according to the image generating information or the mode signal.

In some implementations, the image generating information may include a zoom signal or a zoom factor. Also, in some implementations, the mode signal may include, for example, a signal based on a mode selected by the user.

When the image generating information includes the zoom signal (the zoom factor) and the camera modules 2100a, 2100b, and 2100c have different fields of view (viewing angles), the image generator 2214 may perform different operations depending on types of the zoom signal. For example, when the zoom signal is a first signal, the image data output from the camera module 2100a may be merged with the image data output from the camera module 2100c, and then the merged image signal and the image data output from the camera module 2100b that has not been used in the merging may be used, thereby generating the output image. When the zoom signal is a second signal different from the first signal, the image generator 2214 may generate the output image by selecting any one piece of image data output from each of the camera modules 2100a, 2100b, and 2100c without performing the merging of image data described above. However, the present disclosure is not limited thereto, and a method of processing the image data may be modified if necessary.

In some implementations, the image generator 2214 may receive a plurality of pieces of image data having different exposure times from at least one of the plurality of sub-image processors 2212a, 2212b, and 2212c, and may perform high dynamic range (HDR) processing on the plurality of pieces of image data, thereby generating merged image data having an increased dynamic range.

The camera module controller 2216 may provide a control signal to each of the camera modules 2100a, 2100b, and 2100c. The control signals generated from the camera module controller 2216 may be provided to the corresponding camera modules 2100a, 2100b, and 2100c via separate control signal lines CSLa, CSLb, and CSLc, respectively.

One of the plurality of camera modules 2100a, 2100b, and 2100c may be designated as a master camera module (e.g., 2100b) according to the image generating information including the zoom signal or the mode signal, and the other camera modules (e.g., 2100a and 2100c) may be designated as slave cameras. The information described above may be included in the control signal and provided to the corresponding camera modules 2100a, 2100b, and 2100c via the separate control signal lines CSLa, CSLb, and CSLc, respectively.

The camera module that operates as a master or a slave may change depending on the zoom factor or an operating mode signal. For example, when the camera module 2100a has a viewing angle greater than that of the camera module 2100b and the zoom factor shows a low zoom ratio, the camera module 2100b may operate as the master and the camera module 2100a may operate as the slave. On the contrary, when the zoom factor shows a high zoom ratio, the camera module 2100a may operate as the master and the camera module 2100b may operate as the slave.

In some implementations, the control signal provided to each of the camera modules 2100a, 2100b, and 2100c from the camera module controller 2216 may include a sync enable signal. For example, when the camera module 2100b is a master camera and the camera modules 2100a and 2100c are slave cameras, the camera module controller 2216 may transmit the sync enable signal to the camera module 2100b. The camera module 2100b that has received the sync enable signal may generate a sync signal on the basis of the received sync enable signal and provide the generated sync signal to the camera modules 2100a and 2100c via a sync signal line SSL. The camera module 2100b and the camera modules 2100a and 2100c may be synchronized to this sync signal and transmit the image data to the AP 2200.

In some implementations, the control signals provided from the camera module controller 2216 to the plurality of camera modules 2100a, 2100b, and 2100c may include mode information according to the mode signal. Based on the mode information, the plurality of camera modules 2100a, 2100b, and 2100c may operate in a first operating mode and a second operating mode with respect to a sensing speed.

In the first operating mode, the plurality of camera modules 2100a, 2100b, and 2100c may generate an image signal at a first speed (e.g., generate an image signal with a first frame rate), encode the generated image signal at a second speed higher than the first speed (for example, encode the image signal with a second frame rate higher than the first frame rate), and transmit the encoded image signal to the AP 2200.

The AP 2200 may store the received image signal, i.e., the encoded image signal, in the memory 2230 provided therein or in the storage 2400 outside the AP 2200, and may then read and decode the image signal encoded from the memory 2230 or the storage 2400 and display image data generated based on the decoded image data. For example, among the plurality of sub-image processors 2212a, 2212b, and 2212c of the image processing device 2210, a corresponding sub-processor may perform decoding and also perform image processing on the decoded image signal.

In the second operating mode, the plurality of camera modules 2100a, 2100b, and 2100c may generate an image signal at a third speed lower than the first speed (e.g., generate an image signal with a third frame rate lower than the first frame rate) and transmit the image signal to the AP 2200. The image signal provided to the AP 2200 may include an unencoded signal. The AP 2200 may perform image processing on the received image signal or store the image signal in the memory 2230 or the storage 2400.

The PMIC 2300 may supply power, for example, power supply voltage, to each of the plurality of camera modules 2100a, 2100b, and 2100c. For example, under control by the AP 2200, the PMIC 2300 may supply first power to the camera module 2100a via a power signal line PSLa, supply second power to the camera module 2100b via a power signal line PSLb, and supply third power to the camera module 2100c via a power signal line PSLc.

The PMIC 2300 may generate power corresponding to each of the plurality of camera modules 2100a, 2100b, and 2100c in response to a power control signal PCON from the AP 2200, and may adjust the level of the power. The power control signal PCON may include a power adjustment signal for each of the operating modes of the plurality of camera modules 2100a, 2100b, and 2100c. For example, the operating mode may include a low power mode, and in this case, the power control signal PCON may include information about the camera module that operates in the low power mode and the power level to be set. The levels of power supplied to the plurality of camera modules 2100a, 2100b, and 2100c may be equal to or different from each other. In addition, the levels of power may dynamically change.

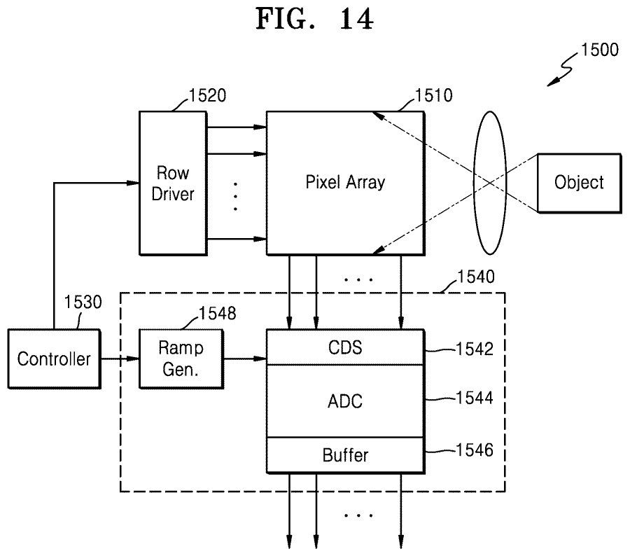

FIG. 14 is a block diagram showing an example of a configuration of an image sensor 1500 according to some implementations. In FIG. 14, the image sensor 1500 may include a pixel array 1510, a controller 1530, a row driver 1520, and a pixel signal processing unit 1540.

The image sensor 1500 may include at least one of the image sensors 1000, 1000a, 1000b, 1000c, 1000d, and 1000e described above. The pixel array 1510 may include a plurality of unit pixels arranged in two dimensions, and each of the unit pixels may include a photodiode. The photodiode may absorb light to generate a photoelectric charge, and an electrical signal (output voltage) according to the generated photoelectric charge may be provided to the pixel signal processing unit 1540 via a vertical signal line.

The unit pixels included in the pixel array 1510 may provide one output voltage at a time in units of rows. Accordingly, the unit pixels belonging to one row of the pixel array 1510 may be simultaneously activated by a selection signal output from the row driver 1520. The unit pixel belonging to the selected row may provide an output voltage according to the absorbed light to an output line of a corresponding column.

The controller 1530 may control the row driver 1520 so that the pixel array 1510 absorbs light to accumulate photoelectric charges, temporarily stores the accumulated photoelectric charges, and outputs an electrical signal based on the stored photoelectric charges to the outside of the pixel array 1510. The controller 1530 may control the pixel signal processing unit 1540 to measure the output voltage provided from the pixel array 1510.

The pixel signal processing unit 1540 may include a correlated double sampler 1542, an analog-to-digital converter 1544, and a buffer 1546. The correlated double sampler 1542 may sample and hold the output voltage provided from the pixel array 1510.

The correlated double sampler 1542 may double-sample a level corresponding to a specific noise level and the generated output voltage, and then output the level corresponding to the difference therebetween. Also, the correlated double sampler 1542 may receive ramp signals generated by a ramp signal generator 1548, compare the ramp signals to each other, and output a comparison result.

The analog-to-digital converter 1544 may convert, into a digital signal, an analog signal corresponding to a level received from the correlated double sampler 1542. The buffer 1546 may latch digital signals, and the latched signals may be sequentially output to the outside of the image sensor 1500 and transmitted to an image processor (not shown).

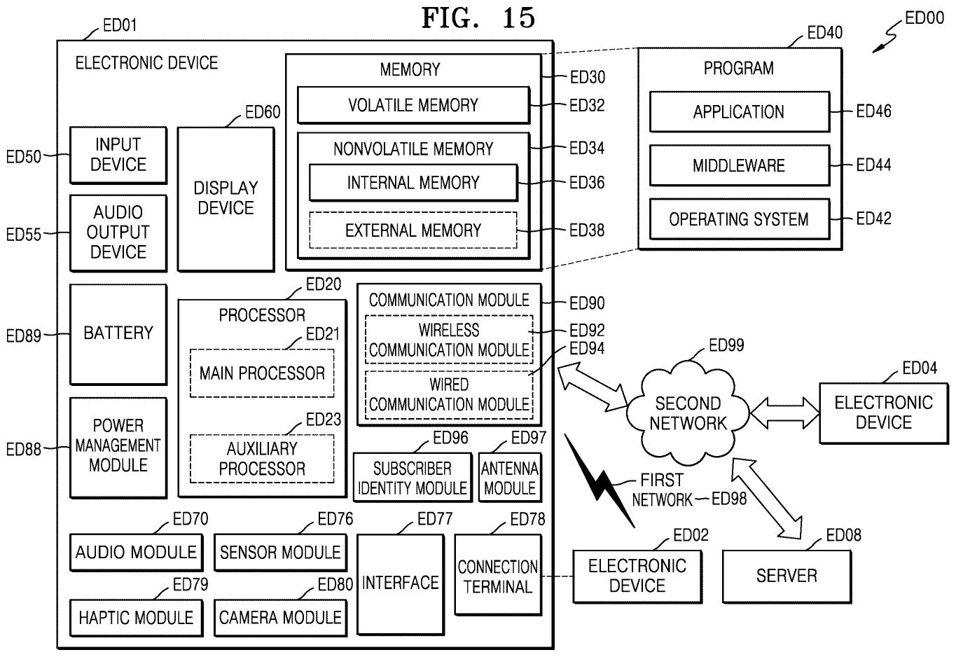

FIG. 15 is a block diagram schematically showing an example of an electronic device including an image sensor according to some implementations. In FIG. 15, in a network environment ED00, an electronic device ED01 may communicate with another electronic device ED02 via a first network ED98 (a short-distance wireless communication network, etc.) or communicate with another electronic device ED04 and/or a server ED08 via a second network ED99 (a long-distance wireless communication network, etc.). The electronic device ED01 may communicate with the electronic device ED04 via the server ED08. The electronic device ED01 may include a processor ED20, memory ED30, an input device ED50, an audio output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. In the electronic device ED01, some of the components (such as the display device ED60) may be omitted, or other components may be added. Some of the components may be provided as a single integrated circuit. For example, the sensor module ED76 (a fingerprint sensor, an iris sensor, an illuminance sensor, etc.) may be embedded in the display device ED60 (a display, etc.).

The processor ED20 may execute software (a program ED40, etc.) to control one or a plurality of other components (hardware, software components, etc.) of the electronic device ED01 connected to the processor ED20 and may perform various data processing or calculations. As part of data processing or calculations, the processor ED20 may load commands and/or data received from other components (the sensor module ED76, the communication module ED90, etc.) into volatile memory ED32, process the commands and/or data stored in the volatile memory ED32, and store the resulting data in non-volatile memory ED34. The processor ED20 may include a main processor ED21 (a central processing unit, an AP, etc.) and an auxiliary processor ED23 (a graphics processing unit, an image signal processor, a sensor hub processor, a communication processor, etc.) that may operate independently of or together with the main processor ED21. The auxiliary processor ED23 may use less power than the main processor ED21 and perform specialized functions.

The auxiliary processor ED23 may control functions and/or states related to some components (the display device ED60, the sensor module ED76, the communication module ED90, etc.) among the components of the electronic device ED01, on behalf of the main processor ED21 while the main processor ED21 is in an inactive state (a sleep state) or together with the main processor ED21 while the main processor ED21 is in an active state (an application execution state). The auxiliary processor ED23 (an image signal processor, a communication processor, etc.) may also be provided as part of other functionally related components (the camera module ED80, the communication module ED90, etc.).

The memory ED30 may store various pieces of data needed by components (the processor ED20, the sensor module ED76, etc.) of the electronic device ED01. The data may include, for example, software (the program ED40, etc.) and input data and/or output data of a command related to the software. The memory ED30 may include the volatile memory ED32 and/or the non-volatile memory ED34. The non-volatile memory ED32 may include internal memory ED36 mounted and fixed in the electronic device ED01 and external memory ED38 detachable from the electronic device ED01.

The program ED40 may be stored as software in the memory ED30 and include an operating system ED42, middleware ED44, and/or an application ED46.

The input device ED50 may receive commands and/or data to be used in components (the processor ED20, etc.) of the electronic device ED01 from the outside (a user, etc.) of the electronic device ED01. The input device ED50 may include a microphone, a mouse, a keyboard, and/or a digital pen (a stylus pen, etc.).

The audio output device ED55 may output acoustic signals to the outside of the electronic device ED01. The audio output device ED55 may include a speaker and/or a receiver. The speaker may be used for general purposes, such as multimedia playback or recording playback, and the receiver may be used to receive incoming calls. The receiver may be integrated as part of the speaker or provided as a separate independent device.

The display device ED60 may visually provide information to the outside of the electronic device ED01. The display device ED60 may include a display, a hologram device, or a projector, and a control circuit for controlling the devices. The display device ED60 may include touch circuitry set to sense touch and/or sensor circuitry (a pressure sensor, etc.) set to measure the intensity of force generated by the touch.

The audio module ED70 may convert sound into an electrical signal or, conversely, convert the electrical signal into the sound. The audio module ED70 may obtain sound via the input device ED50, or may output the sound via the audio output device ED55 and/or via a speaker and/or a headphone of another electronic device (the electronic device ED02, etc.) connected directly or wirelessly to the electronic device ED01.

The sensor module ED76 may sense operating conditions (power, temperature, etc.) of the electronic device ED01 or external environmental conditions (a user state, etc.) and may generate electrical signals and/or data values corresponding to the sensed conditions. The sensor module ED76 may include a gesture sensor, a gyro sensor, a barometric pressure sensor, a magnetic sensor, an acceleration sensor, a grip sensor, a proximity sensor, a color sensor, an IR sensor, a biometric sensor, a temperature sensor, a humidity sensor, and/or an illuminance sensor.

The interface ED77 may support one or a plurality of designated protocols that may be used to directly or wirelessly connect the electronic device ED01 to another electronic device (the electronic device ED02, etc.). The interface ED77 may include a high definition multimedia interface (HDMI), a universal serial bus (USB) interface, a security digital (SD) card interface, and/or an audio interface.

A connection terminal ED78 may include a connector that physically connects the electronic device ED01 to another electronic device (the electronic device ED02, etc.). The connection terminal ED78 may include an HDMI connector, a USB connector, an SD card connector, and/or an audio connector (a headphone connector, etc.).

The haptic module ED79 may convert electrical signals into mechanical stimulation (vibration, movement, etc.) or electrical stimulation that is perceived by a user through tactile or kinesthetic sense. The haptic module ED79 may include a motor, a piezoelectric element, and/or an electrical stimulation device.

The camera module ED80 may capture still images and moving images. The camera module ED80 may include a lens assembly including one or a plurality of lenses, the image sensor 1000, 1000a, 1000b, 1000c, 1000d, or 1000e, image signal processors, and/or flashlights. The lens assembly in the camera module ED80 may collect light emitted from a subject to be image-captured.

The power management module ED88 may manage power supplied to the electronic device ED01. The power management module ED88 may be provided as part of a PMIC.

The battery ED89 may supply power to components of the electronic device ED01. The battery ED89 may include a non-rechargeable primary cell, a rechargeable secondary cell, and/or a fuel cell.

The communication module ED90 may support establishing a direct (wired) communication channel and/or a wireless communication channel between the electronic device ED01 and other electronic devices (the electronic device ED02, the electronic device ED04, the server ED08, etc.) and also support performing the communication via the established communication channel. The communication module ED90 may operate independently of the processor ED20 (the AP, etc.) and include one or a plurality of communication processors that support direct communication and/or wireless communication. The communication module ED90 may include a wireless communication module ED92 (a cellular communication module, a short-distance wireless communication module, a global navigation satellite system (GNSS) communication module, etc.) and/or a wired communication module ED94 (a local area network (LAN) communication module, a power line communication module, etc.). Among these communication modules, the corresponding communication module may communicate with other electronic devices via the first network ED98 (a short-distance communication network, such as Bluetooth, WiFi Direct, and infrared data association (IrDA)) or the second network ED99 (a long-distance communication network, such as a cellular network, Internet, and a computer network (LAN, WAN, etc.)). These various types of communication modules may be integrated into a single component (a single chip, etc.) or may be provided as a plurality of separate components (multiple chips). The wireless communication module ED92 may identify and authenticate the electronic device ED01 in the communication network, such as the first network ED98 and/or the second network ED99, by using subscriber information (an international mobile subscriber identifier (IMSI), etc.) stored in the subscriber identification module ED96.

The antenna module ED97 may transmit signals and/or power to or receive signals and/or power from the outside (other electronic devices, etc.). The antenna may include an emitter including a conductive pattern formed on a substrate (a printed circuit board (PCB), etc.). The antenna module ED97 may include one or a plurality of antennas. When the plurality of antennas are provided, an antenna among the plurality of antennas, which is suitable for the communication method used in the communication network, such as the first network ED98 and/or the second network ED99, may be selected by the communication module ED90. The signals and/or power may be transmitted or received between the communication module ED90 and other electronic devices via the selected antenna. In addition to the antenna, other components (a radio frequency integrated circuit (RFIC), etc.) may be provided as part of the antenna module ED97.

Some of the components may be connected to each other via communication methods between peripheral devices (a bus, a general purpose input and output (GPIO), a serial peripheral interface (SPI), a mobile industry processor interface (MIPI), etc.) and may exchange signals (commands, data, etc.).

The commands or data may be transmitted or received between the electronic device ED01 and the external electronic device ED04 via the server ED08 connected to the second network ED99. The other electronic devices ED02 and ED04 may be the same type of device as the electronic device ED01 or may be a different type of device than the electronic device ED01. All or some of operations executed in the electronic device ED01 may be executed in one or more of the other electronic devices ED02, ED04, and ED08. For example, when the electronic device ED01 needs to perform certain functions or services, the electronic device ED01 may request one or more other electronic devices to perform some or all of the functions or services, instead of autonomously executing the functions or services by itself. The one or more other electronic devices that receive the request may execute additional functions or services related to the request and may transmit the result of executions to the electronic device ED01. To this end, cloud computing, distributed computing, and/or client-server computing techniques may be used.

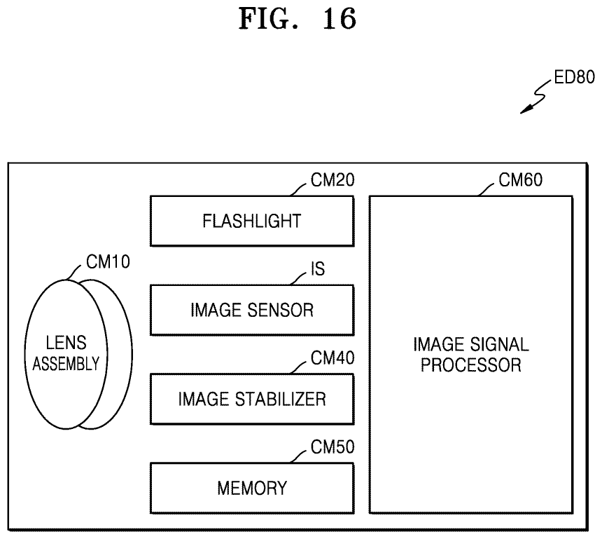

FIG. 16 is a block diagram schematically showing the camera module ED80 of FIG. 15 according to some implementations. In FIG. 16, the camera module ED80 may include a lens assembly CM10, a flashlight CM20, an image sensor IS (the image sensor 1000, 1000a, 1000b, 1000c, 1000d, or 1000e according to the inventive concept), an image stabilizer CM40, memory CM50 (buffer memory, etc.), and/or an image signal processor CM60. The lens assembly CM10 may collect light that is emitted from a subject to be image-captured. The camera module ED80 may include a plurality of lens assemblies CM10, and in this case, the camera module ED80 may constitute a dual camera, a 360-degree camera, or a spherical camera. Some of the plurality of lens assemblies CM10 may have the same lens properties (field of view, focal length, autofocus, F number, optical zoom, etc.) or different lens properties. The lens assembly CM10 may include a wide-angle lens or a telephoto lens.

The flashlight CM20 may emit light that is used to enhance the light emitted from or reflected by the subject. The flashlight CM20 may include one or more light-emitting diodes (red-green-blue (RGB) LED, white LED, infrared LED, ultraviolet LED, etc.) and/or a xenon lamp. The image sensor IS may convert light, which is emitted or reflected from a subject and transmitted via the lens assembly CM10, into an electrical signal, thereby obtaining an image corresponding to the subject. The image sensor IS may include one or more sensors selected from among image sensors having different characteristics, such as RGB sensors, black and white (BW) sensors, IR sensors, and UV sensors. Each of the sensors in the image sensor IS may be formed as a charged coupled device (CCD) sensor and/or a complementary metal oxide semiconductor (CMOS) sensor.

In response to the movement of the camera module ED80 or the electronic device ED01 including the camera module ED80, the image stabilizer CM40 may move one or more lenses of the lens assembly CM10 or the image sensor IS in a specific direction or may control the operation characteristics of the image sensor IS (such as adjusting read-out timing), thereby compensating for a negative impact due to the movement. The image stabilizer CM40 may sense the movement of the camera module ED80 or the electronic device ED01 by using a gyro sensor or an acceleration sensor located inside or outside the camera module ED80. The image stabilizer CM40 may also be formed optically.

The memory CM50 may store some or all of the data about the image obtained by the image sensor IS, for subsequent image processing. For example, when a plurality of images are obtained at a high speed, the obtained raw data (Bayer-Patterned data, high-resolution data, etc.) is stored in memory CM50 and only low-resolution images are displayed. Then, the raw data of the selected image (selected by a user or the like) may be transmitted to the image signal processor CM60. The memory CM50 may be integrated into the memory ED30 of the electronic device ED01 or may be configured as a separate memory that operates independently.

The image signal processor CM60 may perform image processing on images obtained from the image sensor IS or image data stored in the memory CM50. The image processing may include creation of a depth map, three-dimensional modeling, creation of a panorama, extraction of features, image composition, and/or image compensation (noise reduction, resolution adjustment, brightness adjustment, blurring, sharpening, softening, etc.). The image signal processor CM60 may perform control (exposure time control or read-out timing control) on the components (the image sensor IS, etc.) of the camera module ED80. The image processed by the image signal processor CM60 may be stored again in the memory CM50 for further processing or may be provided to external components (the memory ED30, the display device ED60, the electronic device ED02, the electronic device ED04, and the server ED08) of the camera module ED80. The image signal processor CM60 may be integrated into the processor ED20 or may be configured as a separate processor that operates independently of the processor ED20. When the image signal processor CM60 is configured as a separate processor from the processor ED20, the image processed by the image signal processor CM60 may be subjected to additional image processing by the processor ED20 and then displayed via the display device ED60.

The electronic device may include a plurality of camera modules ED80 having different characteristics or functions. In this case, one of the plurality of camera modules ED80 may be a wide-angle camera, and one other of the plurality of camera modules ED80 may be a telephoto camera. Similarly, one of the plurality of camera modules ED80 may be a front-side camera, and one other of the plurality of camera modules ED80 may be a back-side camera.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An image sensor comprising:
a substrate comprising a pixel region and a peripheral region surrounding the pixel region, wherein a plurality of pixels are arranged in the pixel region;
a plurality of color filters above the substrate;
at least one meta-microlens array above the plurality of color filters, the at least one meta-microlens array comprising a plurality of nanoposts and a dielectric layer between the plurality of nanoposts; and
a planarization layer between the plurality of color filters and the at least one meta-microlens array,
wherein the planarization layer contacts the plurality of color filters, and
wherein the planarization layer comprises an inorganic material.

2. The image sensor of claim 1, further comprising an etch stop layer between the planarization layer and the at least one meta-microlens array,
wherein an upper surface of the planarization layer contacts a lower surface of the etch stop layer.

3. The image sensor of claim 1, further comprising an anti-reflection layer on the at least one meta-microlens array.

4. The image sensor of claim 3, wherein the anti-reflection layer comprises a pattern having a hole structure.

5. The image sensor of claim 3, wherein the anti-reflection layer completely covers an upper surface of the least one meta-microlens array.

6. The image sensor of claim 1, wherein the planarization layer is a single layer.

7. The image sensor of claim 1, wherein the planarization layer comprises a plurality of layers.

8. An image sensor comprising:
a substrate comprising a pixel region and a peripheral region surrounding the pixel region, wherein a plurality of pixels are arranged in the pixel region;
an anti-reflection structure on the substrate;
a plurality of color filters above the anti-reflection structure and in the pixel region;
at least one meta-microlens array above the plurality of color filters, the at least one meta-microlens array comprising a plurality of nanoposts and a dielectric layer between the plurality of nanoposts; and
a planarization layer between the plurality of color filters and the at least one meta-microlens array,
wherein the pixel region comprises a pixel array region,
wherein the pixel array region comprises the plurality of pixels and a light-blocking region having a light-blocking layer,
wherein the planarization layer contacts the plurality of color filters and the light-blocking layer, and
wherein the planarization layer comprises an inorganic material.

9. The image sensor of claim 8, wherein the light-blocking layer comprises:
a first light-blocking layer on the anti-reflection structure; and
a second light-blocking layer between the first light-blocking layer and the planarization layer.

10. The image sensor of claim 9, wherein the planarization layer contacts an upper surface of the second light-blocking layer and a side surface of the second light-blocking layer.

11. The image sensor of claim 8, wherein the plurality of nanoposts are arranged over the pixel region.

12. The image sensor of claim 8,
wherein the at least one meta-microlens array comprises a plurality of dummy nanoposts, and
wherein the plurality of dummy nanoposts are arranged over the peripheral region.

13. The image sensor of claim 8, comprising an anti-reflection layer on the at least one meta-microlens array,
wherein the anti-reflection layer comprises a pattern having a hole structure, and
wherein the pattern is located over the pixel region.

14. The image sensor of claim 8,
wherein the at least one meta-microlens array comprises a plurality of meta-microlens arrays, and
wherein an etch stop layer is located between at least two of the plurality of meta-microlens arrays.

15. The image sensor of claim 8, wherein the planarization layer comprises at least one of silicon oxide, silicon nitride, and silicon oxynitride.

16. The image sensor of claim 8, wherein a vertical thickness from upper surfaces of the plurality of color filters to an upper surface of the planarization layer is in a range of about 300 nm to about 1000 nm.

17. An image sensor comprising:
a first substrate comprising a pixel region and a peripheral region surrounding the pixel region, wherein a plurality of pixels are arranged in the pixel region, and the first substrate has a front side and a back side opposite to the front side;
a first wire layer on the back side of the first substrate;
an anti-reflection structure on the front side of the first substrate;
a second substrate below a lower surface of the first wire layer;
a second wire layer between the second substrate and the first wire layer;
a plurality of color filters above the anti-reflection structure, the plurality of color filters being in the pixel region;
at least one meta-microlens array above the plurality of color filters, the at least one meta-microlens array comprising a plurality of nanoposts and a dielectric layer between the plurality of nanoposts; and
a planarization layer between the plurality of color filters and the at least one meta-microlens array,
wherein the pixel region comprises a pixel array region,
wherein the pixel array region comprises the plurality of pixels, and a light-blocking region having a light-blocking layer,
wherein the peripheral region comprises a contact region having a back-side contact, a back-side via region having a back-side via, and a pad region having a pad,
wherein the back-side contact extends through the anti-reflection structure from above the anti-reflection structure to a deep trench isolation,
wherein the deep trench isolation separates the plurality of pixels from each other,
wherein the planarization layer contacts the plurality of color filters and the light-blocking layer, and
wherein the planarization layer comprises an inorganic material.

18. The image sensor of claim 17,
wherein the peripheral region comprises a back-side via region between the contact region and the pad region, and a first back-side via, and
wherein the first back-side via extends through the anti-reflection structure and the first substrate from above the anti-reflection structure to the second wire layer.

19. The image sensor of claim 17,
wherein the light-blocking layer comprises a first light-blocking layer on the anti-reflection structure and a second light-blocking layer between the first light-blocking layer and the planarization layer,
wherein the image sensor comprises a protective layer on the anti-reflection structure and covering the first light-blocking layer, and
wherein the planarization layer contacts the protective layer.

20. The image sensor of claim 17,
wherein a vertical thickness from upper surfaces of the plurality of color filters to an upper surface of the planarization layer is in a range of about 300 nm to about 1000 nm, and
wherein a vertical thickness from a lowermost surface of the planarization layer to the upper surface of the planarization layer is in a range of about 500 nm to about 2000 nm.
